(19) United States
(12) Patent Application Publication
(10) Pub. No.: US 2025/0132203 A1
(43) Pub. Date: Apr. 24, 2025

(54) METHOD FOR MANUFACTURING SEMICONDUCTOR DEVICES

(71) Applicant: Samsung Electronics Co., Ltd., Suwon-si (KR)

(72) Inventors: Song Yi BAEK, Suwon-si (KR); Geumbi MUN, Suwon-si (KR); Junga LEE, Suwon-si (KR); Okran KIM, Suwon-si (KR); Seyoung HWANG, Suwon-si (KR); Kyoungchul SHIN, Suwon-si (KR); Sungsoo YANG, Suwon-si (KR); Daekwang WOO, Suwon-si (KR)

(73) Assignee: Samsung Electronics Co., Ltd., Suwon-si (KR)

(21) Appl. No.: 18/758,118

(22) Filed: Jun. 28, 2024

(30) Foreign Application Priority Data
Oct. 19, 2023 (KR) 10-2023-0140495

(51) Int. Cl. H01L 21/768; H01L 21/311; H01L 21/3213

(52) U.S. Cl. CPC H01L 21/76885; H01L 21/31138; H01L 21/32136; H01L 21/76831

(57) ABSTRACT

A method for manufacturing a semiconductor device. The method may include forming an insulating interlayer on a substrate, forming tungsten patterns inside and on the insulating interlayer, forming an insulation pattern on the insulating interlayer to fill a space between the tungsten patterns, and the insulation pattern having a lowest point of an upper surface lower than an upper surface of each of the tungsten patterns, forming a preliminary tungsten oxide layer on the upper surface of each of the tungsten patterns, performing a first surface plasma treatment on the preliminary tungsten oxide layer to remove at least a portion of the preliminary tungsten oxide layer to form a tungsten oxide layer and a protective layer on the tungsten oxide layer, and forming an etch stop layer on the protective layer and the insulation pattern.

### CROSS-REFERENCE TO RELATED APPLICATION

This application claims priority under 35 USC § 119 to Korean Patent Application No. 10-2023-0140495, filed on Oct. 19, 2023, in the Korean Intellectual Property Office (KIPO), the contents of which are incorporated by reference herein in their entirety.

### BACKGROUND

Various example embodiments relate to a method for method for manufacturing a semiconductor device. Particularly, various example embodiments relate to a method for manufacturing a semiconductor device including a conductive structure.

A semiconductor device may include a conductive structure. An etch stop layer may be formed on the conductive structure. A contact plug may be formed through the etch stop layer, and may contact the conductive structure. In order to reduce defects between the conductive structure and the contact plug, the etch stop layer may be formed to have a more uniform thickness.

### SUMMARY

Various example embodiments provide a method for manufacturing a semiconductor device including a conductive structure.

According to some example embodiments, there is provided a method for manufacturing a semiconductor device. The method may include forming an insulating interlayer on a substrate, forming tungsten patterns inside and on the insulating interlayer, forming an insulation pattern on the insulating interlayer to fill a space between the tungsten patterns, and the insulation pattern having a lowest point of an upper surface lower than an upper surface of each of the tungsten patterns, forming a preliminary tungsten oxide layer on the upper surface of each of the tungsten patterns, performing a first surface plasma treatment on the preliminary tungsten oxide layer to remove at least a portion of the preliminary tungsten oxide layer to form a tungsten oxide layer and a protective layer on the tungsten oxide layer, and forming an etch stop layer on the protective layer and the insulation pattern.

According to some example embodiments, there is provided there is provided a method for manufacturing a semiconductor device. The method may include forming bit line structures on a cell region of a substrate, forming gate structures on a peripheral circuit region of the substrate, forming an insulating interlayer covering the gate structures on the peripheral circuit region of the substrate, forming lower contact plugs contacting the substrate and landing pad patterns including tungsten on the lower contact plugs, the lower contact plugs and the landing pad patterns between the bit line structures, forming first conductive structures including tungsten on the insulating interlayer, the first conductive structures passing through the insulating interlayer and contacting a surface of the substrate, forming insulation patterns between the landing pad patterns and between the first conductive structures, forming a preliminary tungsten oxide layer on upper surfaces of the landing pad patterns and the first conductive structures, respectively, performing a first surface plasma treatment on the preliminary tungsten oxide layer to remove at least a portion of the preliminary tungsten oxide layer to form a tungsten oxide layer and a protective layer on the tungsten oxide layer, forming an etch stop layer on the protective layer and the insulation pattern, forming capacitors on the landing pad patterns, the capacitors passing through the etch stop layer, the protective layer, and the tungsten oxide layer on the cell region of the substrate, and forming contact plugs contacting an upper surface of the first conductive structures, the contact plugs passing through the etch stop layer, the protective layer, and the tungsten oxide layer on the peripheral circuit region of the substrate.

According to some example embodiments, there is provided there is provided a method for manufacturing a semiconductor device. The method may include forming lower structures on a substrate, forming a first lower insulating interlayer including silicon oxide on the lower structures, forming a second lower insulating interlayer including silicon nitride on the first lower insulating interlayer, forming tungsten patterns on the second lower insulating interlayer, and the tungsten patterns passing through the first and second lower insulating interlayers, forming insulation patterns including silicon nitride on the second lower insulating interlayers, the insulation patterns filling a space between the tungsten patterns and having a lowest point of an upper surface lower than an upper surface of each of the tungsten patterns, forming a preliminary tungsten oxide layer on the upper surface of each of the tungsten patterns, performing a CO plasma treatment on the preliminary tungsten oxide layer to remove at least a portion of the preliminary tungsten oxide layer to form a tungsten oxide layer and a protective layer on the tungsten oxide layer, the protective layer including at least tungsten and carbon, and forming an etch stop layer on the protective layer and the insulation patterns.

In method for manufacturing a semiconductor device according to various example embodiments, the tungsten oxide layer and the protective layer may be formed on the tungsten pattern. A sum of thicknesses of the tungsten oxide layer and the protective layer may be less than a thickness of the preliminary tungsten oxide layer. As the thicknesses of the tungsten oxide layer and the protective layer become thinner, a height of the upper surface of the protective layer may be more uniform. Therefore, the etch stop layer may be formed on the protective layer to have a more uniform thickness. An adhesion property of the etch stop layer on the protective layer may be excellent. Therefore, defects that occur when the etch stop layer has a non-uniform thickness may be decreased.

### BRIEF DESCRIPTION OF THE DRAWINGS

Various example embodiments will be more clearly understood from the following detailed description taken in conjunction with the accompanying drawings. FIGS. 1 to 42 represent various non-limiting, example embodiments as described herein.

FIGS. 1 to 10 and 12 are cross-sectional views and enlarged cross-sectional views for illustrating a method for manufacturing a semiconductor device according to example embodiments;

FIG. 11 is a schematic diagram illustrating a reaction mechanism of a CO (carbon monoxide) plasma treatment process and a deposition process of an etch stop layer;

FIGS. 13, 14, 16 to 18 are cross-sectional views and enlarged cross-sectional views for illustrating a method for manufacturing a semiconductor device according to various example embodiments;

FIG. 15 is a schematic diagram illustrating a reaction mechanism of a hydrogen plasma treatment process;

FIG. 19 is a schematic diagram illustrating a reaction mechanism of an NH₃ (ammonia) plasma treatment process and a deposition process of an etch stop layer; and

FIGS. 20 to 42 are plan views and cross-sectional views for illustrating a method for manufacturing a semiconductor device according to various example embodiments.

### DETAILED DESCRIPTION

Hereinafter, various example embodiments will be described in detail with reference to the accompanying drawings.

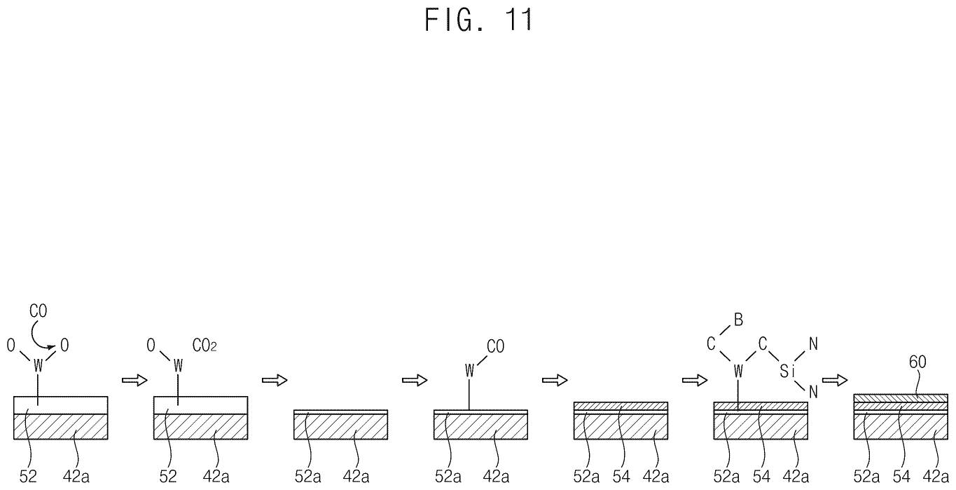

FIGS. 1 to 10 and 12 are cross-sectional views and enlarged cross-sectional views for illustrating a method for manufacturing a semiconductor device according to some example embodiments. FIG. 11 is a schematic diagram illustrating a reaction mechanism of a CO plasma treatment process and a deposition process of an etch stop layer.

FIGS. 6, 8, and 10 are enlarged cross-sectional views illustrating portions of the semiconductor device.

Referring to FIG. 1, a lower structure 25 may be formed on a substrate 10. For example, the lower structure 25 may include a transistor 24. The transistor 24 may include a gate structure 18 and an impurity region 22. The gate structure 18 may include a gate insulation layer 12, a gate electrode 14, and a first capping pattern 16. A gate spacer 20 may be formed on sidewalls of the gate structure 18.

A lower insulating interlayer 34 may be formed on the substrate 10 to cover the lower structures 25. The lower insulating interlayer 34 may include a plurality of insulating interlayers, and an uppermost lower insulating interlayer 34 may include, e.g., silicon nitride. An upper surface of the uppermost lower insulating interlayer 34 may be substantially flat.

In some example embodiments, the lower insulating interlayer 34 may include a first lower insulating interlayer 30 including silicon oxide and a second lower insulating interlayer 32 including silicon nitride.

The lower insulating interlayer 34 may be etched to form a first contact hole 36. The first contact hole 36 may pass through the lower insulating interlayer 34, and may expose a surface of the substrate 10.

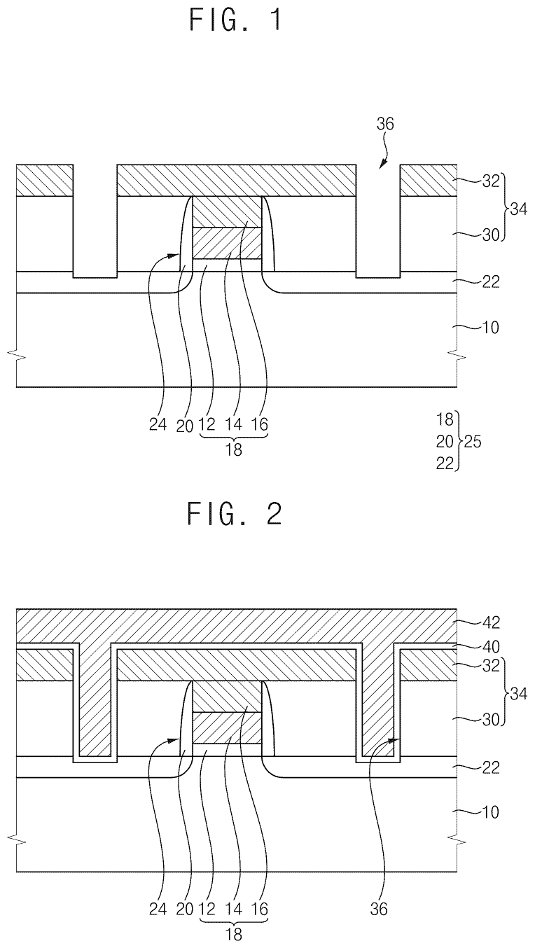

Referring to FIG. 2, a barrier metal layer 40 may be formed on an upper surface of the lower insulating interlayer 34 and a surface of the first contact hole 36. A metal layer 42 may be formed on the barrier metal layer 40.

The barrier metal layer 40 may include, e.g., titanium, titanium nitride, titanium silicon nitride, tantalum, tantalum nitride, etc. In some example embodiments, the process for forming the barrier metal layer 40 may be omitted.

In some example embodiments, the metal layer 42 may include tungsten, copper, hafnium, zirconium, titanium, tantalum, aluminum, ruthenium, palladium, platinum, cobalt, nickel, etc. For example, the metal layer 42 may include tungsten. Hereinafter, the metal layer 42 is referred to as a tungsten layer.

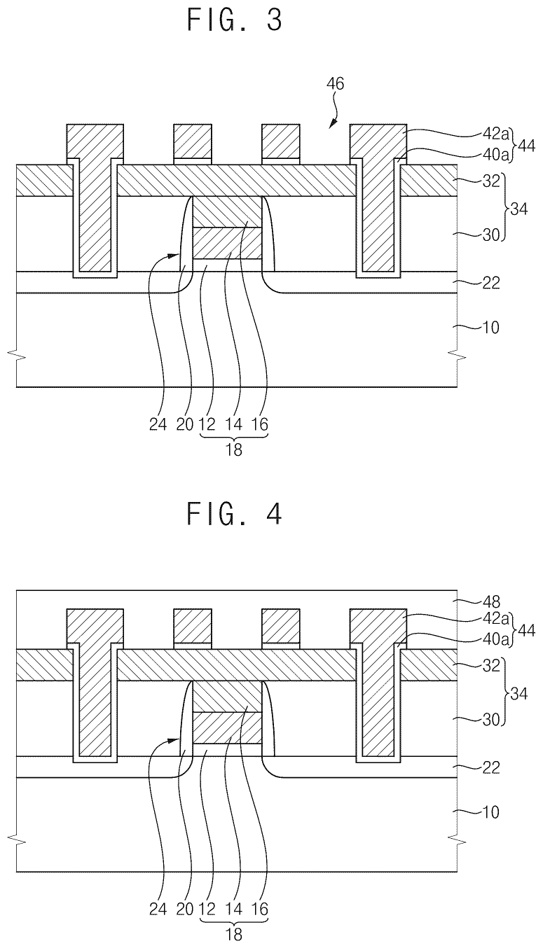

Referring to FIG. 3, the tungsten layer 42 and the barrier metal layer 40 may be etched to form conductive structures 44 in which a barrier metal pattern 40a and a tungsten pattern 42a are stacked. The barrier metal pattern 40a may be conformally formed on the surface of the first contact hole 36 and an upper surface of the second lower insulating interlayer 32. The conductive structures 44 may include a first contact plug filling the first contact hole 36 and a wiring line on the first contact plug.

In some example embodiments, in the etching processes of the tungsten layer 42 and the barrier metal layer 40, an upper portion of the second lower insulating interlayer 32 may be partially etched together. A first opening 46 may be formed between the conductive structures 44 on the second lower insulating interlayer 32. In some example embodiments, the second lower insulating interlayer 32 including silicon nitride may be exposed by a bottom of the first opening 46.

Referring to FIG. 4, a first insulation layer 48 may be formed on the tungsten pattern 42a and the second lower insulating interlayer 32 to fill the first opening 46.

In some example embodiments, the first insulation layer 48 may be a material the same as a material of the second lower insulating interlayer 32. For example, the first insulation layer 48 may include silicon nitride.

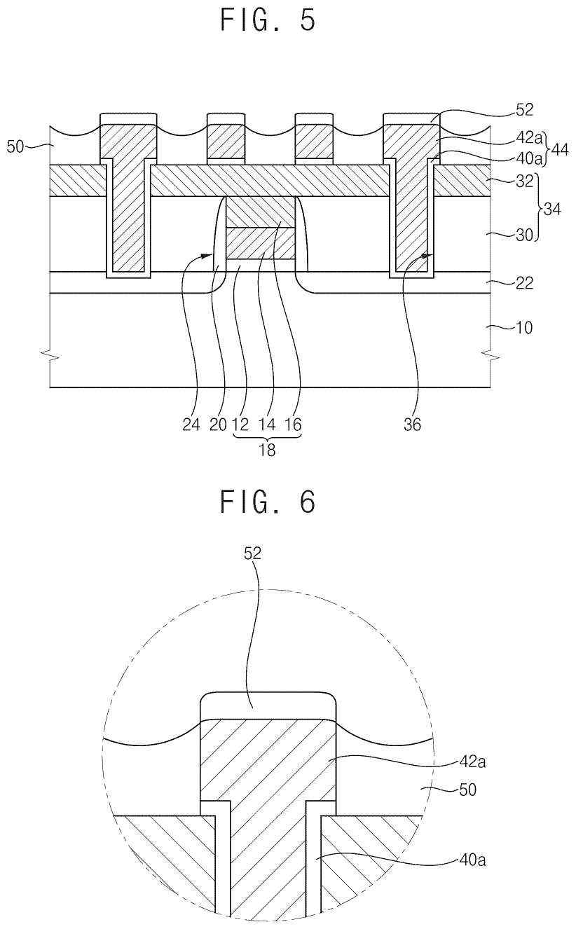

Referring to FIGS. 5 and 6, the first insulation layer 48 may be planarized until an upper surface of the tungsten pattern 42a may be exposed to form an insulation pattern 50. The planarization process may include, e.g., a chemical mechanical polishing process or an etch-back process.

After forming the planarization process, a lowest point of an upper surface of the insulation pattern 50 may be lower than the upper surface of the tungsten pattern 42a. Accordingly, an upper sidewall of the tungsten pattern 42a may be exposed. An upper edge of the tungsten pattern 42a may have a rounded shape.

As the upper surface of the tungsten pattern 42a is exposed, oxygen may be reacted with the surface of the tungsten pattern 42a to form a preliminary tungsten oxide layer 52 on the tungsten pattern 42a.

In some example embodiments, the preliminary tungsten oxide layer 52 may be generated by a native oxidation. In some example embodiments, an ashing process, which is a heat treatment process introducing oxygen, may be further performed on the tungsten pattern 42a and the first insulation layer 48. Therefore, the preliminary tungsten oxide layer 52 may be formed on an exposed surface of the tungsten pattern 42a by the ashing process.

As the upper edge of the tungsten pattern 42a may have the rounded shape, the preliminary tungsten oxide layer 52 may have a rounded shape on the upper edge of the tungsten pattern 42a. Accordingly, a height of an upper surface of the preliminary tungsten oxide layer 52 formed on a central portion of the tungsten pattern 42a may be different from a height of an upper surface of the preliminary tungsten oxide layer 52 formed on an edge portion of the tungsten pattern 42a. For example, an edge portion of the upper surface of the preliminary tungsten oxide layer 52 may be lower than a central portion of the upper surface of the preliminary tungsten oxide layer 52.

The preliminary tungsten oxide layer 52 may have a first thickness in a vertical direction from an upper surface of the central portion of the tungsten pattern 42a.

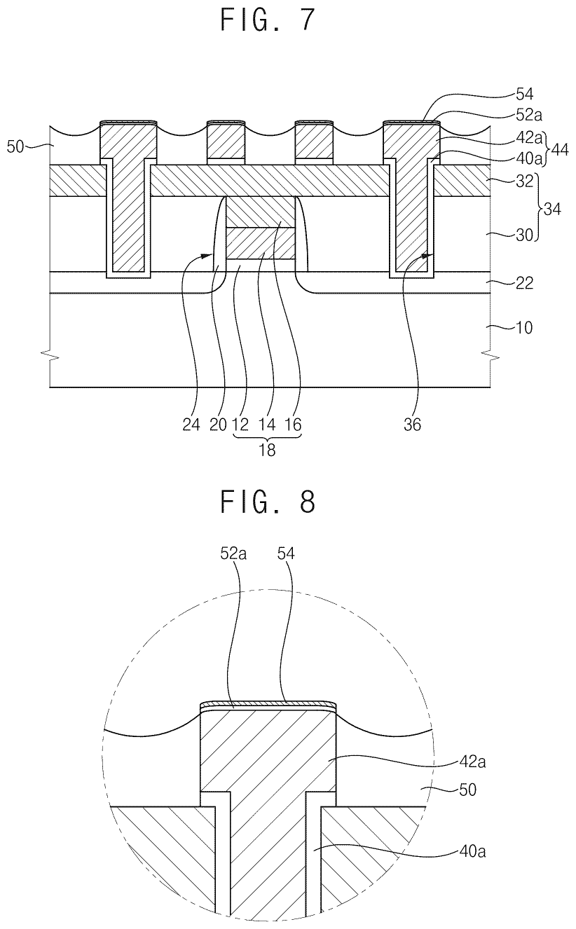

Referring to FIGS. 7 and 8, a surface plasma treatment process may be performed on the preliminary tungsten oxide layer 52. At least a portion of the preliminary tungsten oxide layer 52 may be removed to form a tungsten oxide layer 52a, and a protective layer 54 may be formed on the tungsten oxide layer 52a, by performing the surface plasma treatment process.

In various example embodiments, the surface plasma treatment process may be a CO plasma treatment.

When the CO plasma treatment process is performed on the surface of the preliminary tungsten oxide layer 52, as shown in FIG. 11, oxygen included in the preliminary tungsten oxide layer 52 may be reacted with CO to remove a portion of the preliminary tungsten oxide layer 52. In this case, the tungsten oxide layer 52a may be formed to have a second thickness less than the first thickness of the preliminary tungsten oxide layer 52. The CO plasma treatment process may be performed for about 5 seconds to about 30 seconds. When the CO plasma treatment process is performed for time shorter than 5 seconds, effects of removing the preliminary tungsten oxide layer 52 due to the CO plasma treatment process may be decreased. Even if the CO plasma treatment process is performed for time more than 30 seconds, the thickness of the preliminary tungsten oxide layer 52 may not be additionally decreased.

Additionally, a W—O—C (tungsten-oxide-carbon) bond or a W—C (tungsten-carbon) bond may be generated on the tungsten oxide layer 52a. Accordingly, a protective layer 54 including carbon may be formed on the tungsten oxide layer 52a. The protective layer 54 may be, e.g., a WOC (tungsten oxycarbide) layer or a WC (tungsten carbide) layer.

In some example embodiments, after performing the surface plasma treatment process, a sum of thicknesses of the tungsten oxide layer 52a and the protective layer 54 may be less than the thickness of the preliminary tungsten oxide layer 52. Since the sum of the thicknesses of the tungsten oxide layer 52a and the protective layer 54 formed on the upper surface of the tungsten pattern 42a may be less than the thickness of the preliminary tungsten oxide layer 52, a difference between a height of an upper surface of the protective layer 54 and a height of a lowest point of an upper surface of the insulation pattern 50 may be less than a difference between a height of an upper surface of the preliminary tungsten oxide layer 52 and the height of a lowest point of an upper surface of the insulation pattern 50. Therefore, a height difference between the upper surface of the protective layer 54 and the lowest point of the upper surface of the insulation pattern 50 may be decreased by the surface plasma treatment process.

When the CO plasma treatment process is performed, the preliminary tungsten oxide layer 52 formed on the central portion of the upper surface of the tungsten pattern 42a may be removed more than the preliminary tungsten oxide layer 52 formed on the edge portion of the upper surface of the tungsten pattern 42a. Therefore, when the CO plasma treatment process is performed, the height difference between the upper surface of the tungsten oxide layer 52a formed on the central portion of the tungsten pattern 42a and the upper surface of the tungsten oxide layer 52a formed on the edge portion of the tungsten pattern 42a may be decreased. Accordingly, the height of the upper surface of the tungsten oxide layer 52a may be substantially uniform. Additionally, the height of the upper surface of the protective layer 54 formed on the tungsten oxide layer 52a may be substantially uniform.

If the protective layer 54 includes the WOC layer or the WC layer, hydrogen may not be blocked by the protective layer 54. Therefore, if a diffusing process of the hydrogen in which hydrogen diffuses downward is subsequently performed, the protective layer 54 including the WOC layer or the WC layer may be formed by the CO plasma treatment process, before the diffusing process of the hydrogen.

By the process, the conductive structure 44 including the barrier metal pattern 40a and the tungsten pattern 42a may be formed on the second lower insulating interlayer 32, and the conductive structure 44 may pass through the lower insulating interlayer 34. The tungsten oxide layer 52a and the protective layer 54 may be stacked on the upper surface of the tungsten pattern 42a.

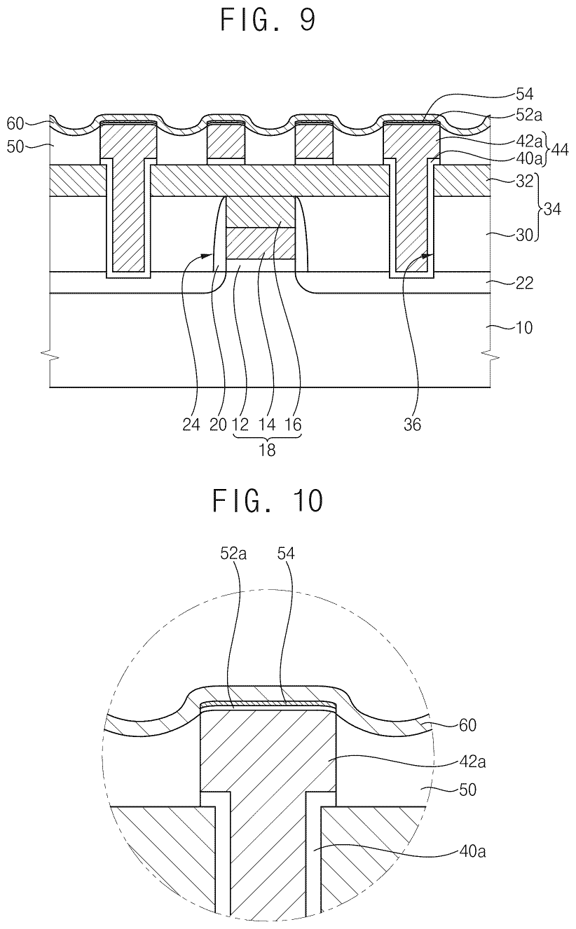

Referring to FIGS. 9 and 10, an etch stop layer 60 may be formed on the upper surface of the protective layer 54 and the insulation pattern 50.

The etch stop layer 60 may include SiBN, SiCN, or SiN. If the diffusing process of the hydrogen is subsequently performed, the hydrogen may not be blocked by the etch stop layer 60. Therefore, the etch stop layer 60 may include, e.g., SiBN as a material through which the hydrogen can diffuse.

Since the upper surface of the protective layer 54 is substantially uniform and the height difference between upper surfaces of the protective layer 54 and the insulation pattern 50 is decreased, the etch stop layer 60 may be formed on the protective layer 54 to have a more uniform thickness.

When the etch stop layer 60 does not have a mostly uniform thickness and has a thickness less than a target thickness on some regions, a metal may grow on the regions of the etch stop layer having a thin thickness. Further, conductive particles may not be blocked by the etch stop layer, so that the conductive particles may penetrate into a layer under the etch stop layer. Therefore, a short failure, which is an upper contact plug subsequently formed is electrically connected to a neighboring tungsten pattern 42a adjacent a target tungsten pattern 42a and the target tungsten pattern 42a to each other, may occur. However, as described above, since the thickness of the etch stop layer 60 is more uniformly formed, the short failure may be decreased.

As the etch stop layer 60 may directly contact the protective layer 54 including WOC or WC, an adhesion property of the etch stop layer 60 may be improved. As shown in FIG. 11, when the etch stop layer 60 including SiBN is formed on the protective layer 54, a bond of W—O—C—SiBN may be generated. Therefore, the adhesion property between the protective layer 54 and the etch stop layer 60 may be improved.

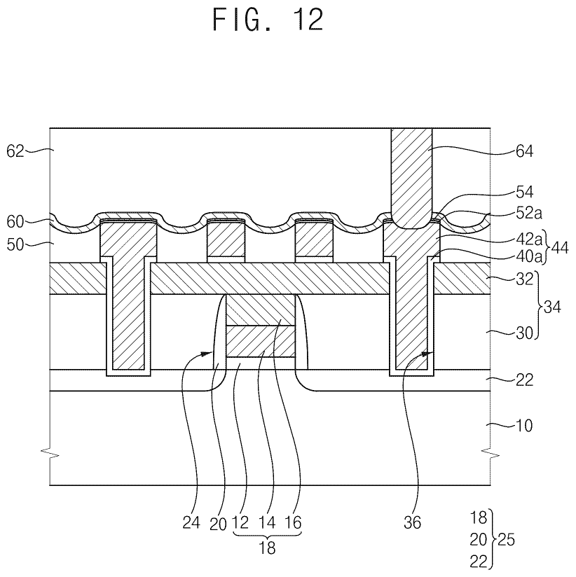

Referring to FIG. 12, an insulating interlayer 62 may be formed on the etch stop layer 60. An upper contact plug 64 may be formed through the insulating interlayer 62, the etch stop layer 60, the protective layer 54, and the tungsten oxide layer 52a, and the upper contact plug 64 may contact an upper surface of a target tungsten pattern 42a.

The upper contact plug 64 may include a metal. The upper contact plug 64 may include a barrier metal pattern and a metal pattern. The metal pattern may include, e.g., tungsten.

As described above, the CO plasma treatment process may be performed on the preliminary tungsten oxide layer 52 to form the tungsten oxide layer 52a and the protective layer 54 having the thickness less than the thickness of the preliminary tungsten oxide layer 52. As a uniformity of the upper surface of the protective layer 54 increases, the etch stop layer 60 may be formed to have a more uniform thickness. Therefore, in the process for forming the upper contact plug 64, a short failure, which is the upper contact plug 56 is electrically connected to the neighboring tungsten pattern 42a adjacent the target tungsten pattern 42a and the target tungsten pattern 42a, may be decreased.

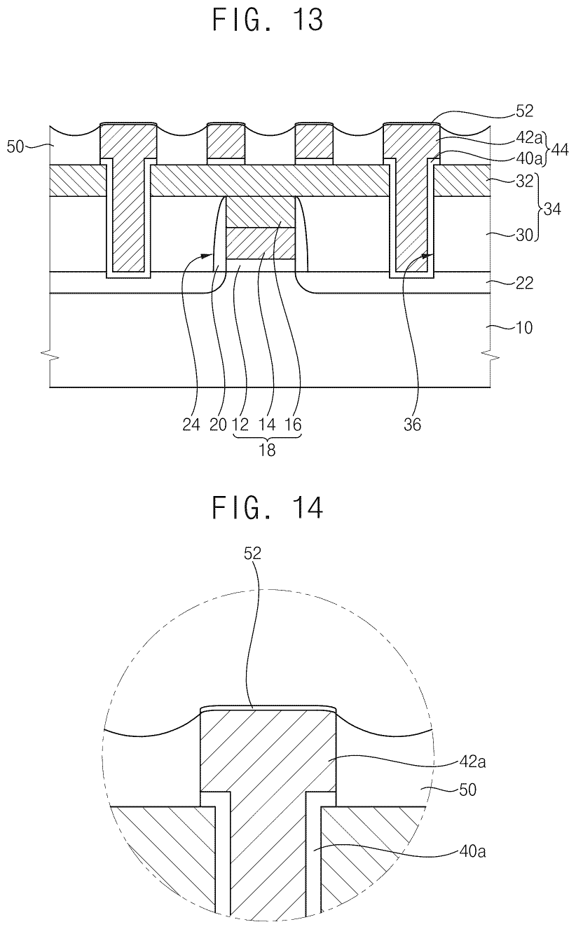

FIGS. 13, 14, 16 to 18 are cross-sectional views and enlarged cross-sectional views for illustrating a method for manufacturing a semiconductor device according to some example embodiments. FIG. 15 is a schematic diagram illustrating a reaction mechanism of a hydrogen plasma treatment process.

FIGS. 14, 17, and 18 are enlarged cross-sectional views illustrating portions of a semiconductor device.

The method of manufacturing a semiconductor device described below may be the same as that described with reference to FIGS. 1 to 12, except for a surface plasma treatment process of a preliminary tungsten oxide layer.

Referring to FIGS. 13 and 14, first, the processes described with reference to FIGS. 1 to 6 may be performed to form the structures shown in FIGS. 5 and 6.

A first surface plasma treatment process may be performed on the preliminary tungsten oxide layer 52, so that at least a portion of the preliminary tungsten oxide layer 52 may be removed. The first surface plasma treatment process may be a hydrogen (H₂) plasma treatment process.

As shown in FIG. 15, when the hydrogen plasma treatment process is performed on a surface of the preliminary tungsten oxide layer 52, the preliminary tungsten oxide layer 52 may be reduced to tungsten by the following reaction equation. Accordingly, the preliminary tungsten oxide layer 52 may be removed.

WOx+H₂→W+H₂O

In various example embodiments, a portion of the preliminary tungsten oxide layer 52 may be removed by the hydrogen plasma treatment process. In this case, as shown in FIG. 14, a thickness of the preliminary tungsten oxide layer 52 may be decreased.

In some example embodiments, the preliminary tungsten oxide layer 52 may be completely removed by the hydrogen plasma treatment process. In this case, an upper surface of the tungsten pattern 42a may be exposed.

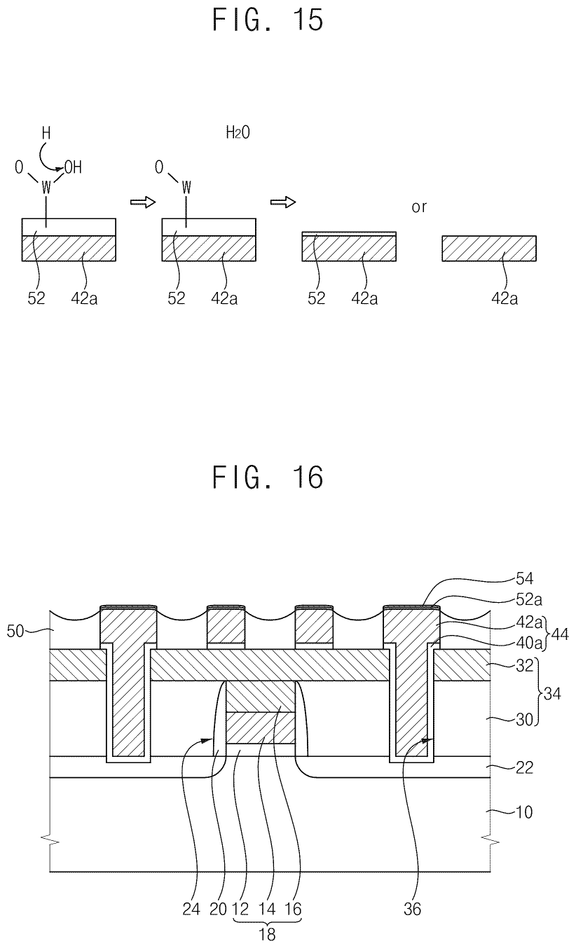

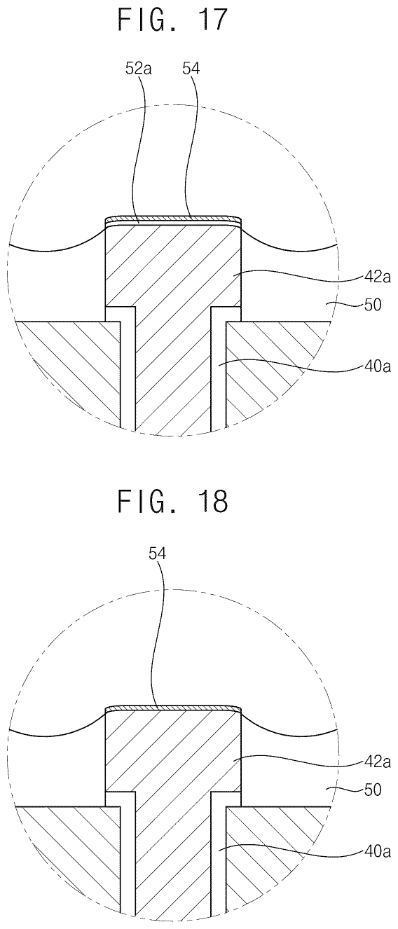

Referring to FIGS. 16 and 17, a second surface plasma treatment process is performed after performing the first surface plasma treatment process. At least a portion of the preliminary tungsten oxide layer 52 may be removed to form a tungsten oxide layer 52a, and a protective layer 54 may be formed on the tungsten oxide layer 52a, by the second surface plasma treatment process.

The second surface plasma treatment process may be a CO plasma treatment process.

When CO plasma treatment is performed on the preliminary tungsten oxide layer 52, a portion of the surface of the preliminary tungsten oxide layer 52 may be removed to form a tungsten oxide layer 52a having a second thickness less than the first thickness. The protective layer 54 may be formed by generating a W—O—C bond or a W—C bond on the tungsten oxide layer 52a. The protective layer 54 may be, e.g., the WOC layer or the WC layer.

By the above process, as shown in FIG. 17, a conductive structure 44 including the barrier metal pattern 40a and the tungsten pattern 42a may be formed on the second lower insulating interlayer 32, and the tungsten oxide layer 52a and the protective layer 54 may be formed on the upper surface of the tungsten pattern 42a.

In some example embodiments, the tungsten oxide layer 52a may be completely removed by the hydrogen plasma treatment process. In this case, an upper surface of the tungsten pattern 42a may be combined to —OC or —C, so that the protective layer 54 may be formed directly on the tungsten pattern 42a. The protective layer 54 may be the WOC layer or the WC layer. As shown in FIG. 18, a conductive structure 44 including the barrier metal pattern 40a and the tungsten pattern 42a may be formed on the second lower insulating interlayer 32, and a protective layer 54 may be formed on the upper surface of the tungsten pattern 42a.

Thereafter, the processes described with reference to FIGS. 9, 10, and 12 may be performed in the same manner to form the etch stop layer 60, the insulating interlayer 62, and the upper contact plug 64, as shown in FIG. 12.

As described above, the surface plasma treatment process of the preliminary tungsten oxide layer may include the CO plasma treatment process. In some example embodiments, the hydrogen plasma treatment process may be further performed, before performing the CO plasma treatment process.

In some example embodiments, only the hydrogen plasma treatment may be performed on the preliminary tungsten oxide layer. When only the hydrogen plasma treatment is performed, the protective layer may not be formed. Therefore, the etch stop layer may directly contact the tungsten pattern or the tungsten oxide layer. Accordingly, the adhesion property of the etch stop layer may not be good.

The surface plasma treatment process performed on the preliminary tungsten oxide layer may be variously modified. Hereinafter, surface plasma treatment processes that can be performed on the preliminary tungsten oxide layer may be described.

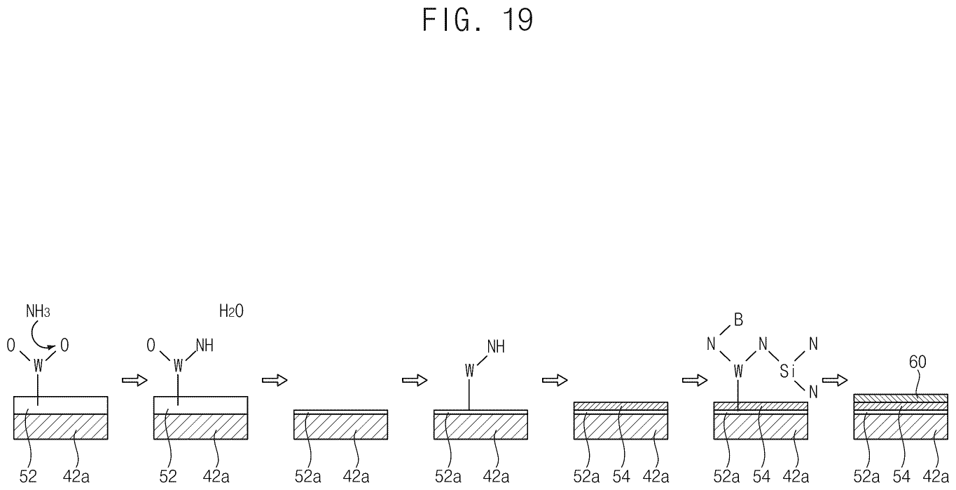

FIG. 19 is a schematic diagram illustrating a reaction mechanism of NH₃ plasma treatment process and a deposition process of an etch stop layer.

First, the processes described with reference to FIGS. 1 to 6 are performed to form the structures shown in FIGS. 5 and 6.

Thereafter, a surface plasma treatment process may be performed on the preliminary tungsten oxide layer. At least a portion of the preliminary tungsten oxide layer may be removed to form a tungsten oxide layer 52a, and a protective layer 54 may be formed on the tungsten oxide layer 52a, by the surface plasma treatment process. The surface plasma treatment process may be, e.g., an NH₃ plasma treatment process.

As shown in FIG. 19, when the NH₃ plasma treatment process is performed on the surface of the preliminary tungsten oxide layer 52, oxygen included in the preliminary tungsten oxide layer 52 may be reacted with NH₃ to remove at least a portion of the preliminary tungsten oxide layer 52. As shown in FIGS. 7 and 8, the preliminary tungsten oxide layer 52 may be transformed into the tungsten oxide layer 52a. The protective layer 54 may be formed on the tungsten oxide layer 52a. The protective layer 54 may include nitrogen, and may be, e.g., a WON (tungsten oxynitride) layer or a WN (tungsten nitride) layer.

An adhesion property between the etch stop layer subsequently formed and the protective layer 54 may be improved by the protective layer 54. As the protective layer 54 is formed, damages of the tungsten pattern 42a may be decreased. As the upper surface of the tungsten oxide layer 52a below the protective layer 54 becomes more uniform, the upper surface of the protective layer 54 may be more uniform.

The NH₃ plasma treatment process may be performed for about 5 seconds to about 30 seconds. If the NH₃ plasma treatment process is performed for time shorter than 5 seconds, effects of removing the preliminary tungsten oxide layer due to surface plasma treatment may be decreased. Even if the NH₃ plasma treatment process is performed for time more than 30 seconds, the thickness of the preliminary tungsten oxide layer may not be additionally decreased.

In various example embodiments, a sum of the thicknesses of the tungsten oxide layer 52a and the protective layer 54 after performing the surface plasma treatment process may be less than the thickness of the preliminary tungsten oxide layer 52.

In various example embodiments, in the NH₃ plasma treatment process, not only NH₃ but also H₂ and/or N₂ gas may be additionally introduced.

Thereafter, the processes described with reference to FIGS. 9, 10, and 12 may be performed in the same manner to form the etch stop layer 60, the insulating interlayer 62, and the upper contact plug 64, as shown in FIG. 12.

As described above, the surface plasma treatment process of the preliminary tungsten oxide layer 52 may include only NH₃ plasma treatment.

When only the NH₃ plasma treatment may be performed, the protective layer may include the WON layer or the WN layer. In this case, the hydrogen may be blocked by the protective layer. If the hydrogen is required to diffuse downward in subsequent processes, the other surface plasma treatment may be additionally performed.

In various example embodiments, the CO plasma treatment and/or the hydrogen plasma treatment may be further performed, before performing the NH₃ plasma treatment. Nitrogen included in the protective layer may be decreased by the CO plasma treatment and/or the hydrogen plasma treatment, so that the hydrogen may not be blocked by the protective layer in subsequent processes.

As described above, the surface plasma treatment process of the preliminary tungsten oxide layer 52 may include, e.g., the CO plasma treatment, H₂ plasma treatment, NH₃ plasma treatment, etc. The plasma treatment process may be performed alone or in combination of two or more of the CO plasma treatment, H₂ plasma treatment, and NH₃ plasma treatment. For example, when the CO plasma treatment process and the NH₃ plasma treatment process are performed on the preliminary tungsten oxide layer 52, the protective layer 54 may include the WOC layer, the WC layer, a WCN (tungsten carbonitride) layer, or a WOCN (tungsten oxycarbonitride) layer.

An effect of removing the tungsten oxide layer by the H₂ plasma treatment may be greater than an effect of removing the tungsten oxide layer by the CO plasma treatment or the NH₃ plasma treatment. Therefore, the H₂ plasma treatment may be performed before performing the CO plasma treatment and NH₃ plasma treatment, so that an entire of tungsten oxide layer or a partial portion of the tungsten oxide layer may be removed.

A semiconductor device formed by the processes described above may have the following structural characteristics.

Referring to FIG. 12 again, a lower structure 25 may be formed on the substrate 10. A lower insulating interlayer 34 may be formed on the substrate 10 and the lower structure 25. The lower insulating interlayer 34 may include a plurality of insulation layers, and an uppermost lower insulating interlayer may include silicon nitride. In various example embodiments, the lower insulating interlayer 34 may include a first lower insulating interlayer 30 including silicon oxide and a second lower insulating interlayer 32 including silicon nitride.

In various example embodiments, as shown in FIGS. 14 and 17, a conductive structure 44 including a barrier metal pattern 40a and a tungsten pattern 42a may be formed on the lower insulating interlayer 34. A tungsten oxide layer 52a and a protective layer 54 may be stacked on the upper surface of the tungsten pattern 42a.

In some example embodiments, as shown in FIG. 18, a conductive structure 44 including a barrier metal pattern 40a and a tungsten pattern 42a may be formed on the lower insulating interlayer 34. A protective layer 54 may be formed on an upper surface of the tungsten pattern 42a.

A plurality of conductive structures 44 may be formed. The conductive structure 44 may pass through the lower insulating interlayer 34, and the conductive structure 44 may contact an upper portion of the substrate 10.

In some example embodiments, the protective layer 54 may be formed by performing a CO plasma treatment process on a preliminary tungsten oxide layer. Therefore, the protective layer 54 may include, e.g., tungsten and carbon. For example, the protective layer 54 may include a WOC layer or a WC layer.

In some example embodiments, the protective layer 54 may be formed by performing an NH₃ plasma treatment process on a preliminary tungsten oxide layer. In this case, the protective layer 54 may include a WON layer or a WN layer.

In some example embodiments, the protective layer 54 may be formed by performing a CO plasma treatment process and an NH₃ plasma treatment process on a preliminary tungsten oxide layer. In this case, the protective layer 54 may include the WOC layer, the WC layer, a WCN layer, or a WOCN layer.

An insulation pattern 50 may be formed between the plurality of conductive structures 44. The insulation pattern 50 may include a material the same as a material of the second lower insulating interlayer 32. In some example embodiments, the insulation pattern 50 may include silicon nitride.

In various example embodiments, a top surface of the insulation pattern 50 may be lower than a top surface of the protective layer 54. In some example embodiments, a lowest point of an upper surface of the insulation pattern 50 may be lower than a top surface of the tungsten oxide layer 52a.

An etch stop layer 60 may cover upper surfaces of the plurality of conductive structures 44, the tungsten oxide layer 52a, the protective layer 54, and the insulation pattern 50. The etch stop layer 60 may include, e.g., SiBN, SiCN, or SiN. For example, the etch stop layer 60 may include SiBN.

An insulating interlayer 62 may be disposed on the etch stop layer 60. An upper contact plug 64 may pass through the insulating interlayer 62 and the etch stop layer 60. The upper contact plug 64 may contact an upper surface of a target tungsten pattern.

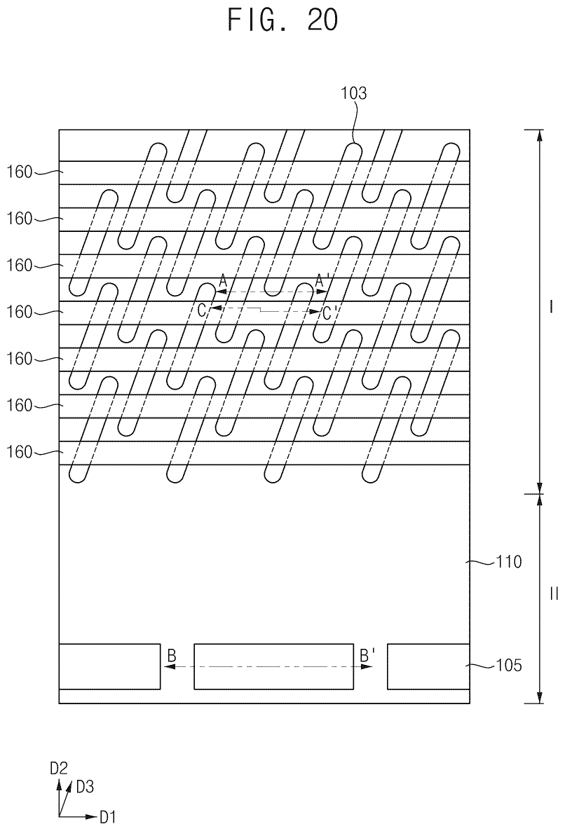

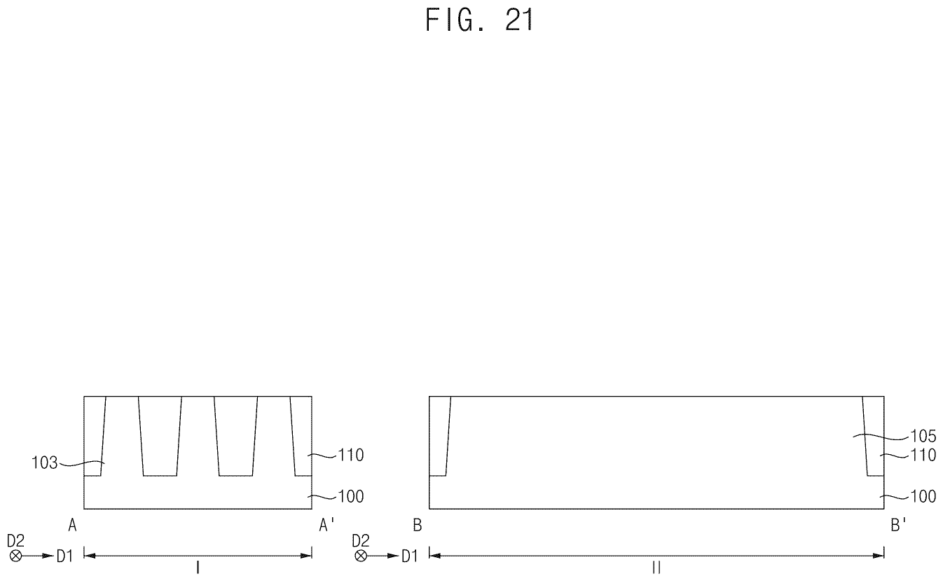

FIGS. 20 to 42 are plan views and cross-sectional views for illustrating a method for manufacturing a semiconductor device according to various example embodiments.

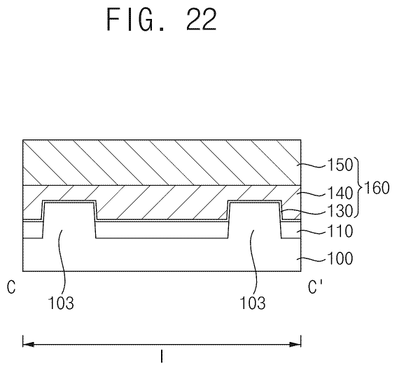

FIGS. 20, 23, 28, and 36 are plan views. FIGS. 21, 24 to 27, 29 to 35, and 37 to 42 are cross-sectional views taken along lines A-A′ and B-B′ of the plan view. FIG. 22 is a cross-sectional view taken along line C-C′ in the plan view.

In detailed descriptions below, two directions parallel to an upper surface of a substrate and perpendicular to each other are defined as a first direction D1 and a second direction D2, respectively. A direction parallel to an upper surface of a substrate and having an acute angle with each of the first and second directions D1 and D2 is defined as a third direction D3.

The semiconductor device may be a DRAM device, and the DRAM device may include a conductive structure.

Referring to FIGS. 20 to 22, first and second active patterns 103 and 105 may be formed on a substrate 100 including first and second regions I and II, respectively. An isolation pattern 110 may be formed between first active patterns 103, between the second active patterns 105, and between the first and second active patterns 103 and 105.

The first region I of the substrate 100 may be a cell region where memory cells are formed. The second region II of the substrate 100 may surround the first region I, and the second region II may be a peripheral circuit region where peripheral circuit patterns for operating the memory cells are formed.

The first and second active patterns 103 and 105 may be defined by a first trench formed by removing an upper portion of the substrate 100. The first active pattern 103 may extend in the third direction D3, and a plurality of first active patterns may be spaced apart from each other in each of the first and second directions D1 and D2. The second active pattern 105 may be formed at a region for forming the peripheral circuit patterns. In order to avoid drawing complexity, only one isolated second active pattern 105 is shown. The isolation pattern 110 may be formed in the first trench.

After forming an impurity region (not shown) at the first region I of the substrate 100 by, e.g., performing an ion implantation process, the first active pattern 103 and the isolation pattern 110 may be partially etched to form a first recess extending in the first direction D1.

A first gate structure 160 may be formed in the first recess. The first gate structure 160 may include a first gate insulation pattern 130 formed on a bottom and side walls of the first recess, a gate electrode formed on the first gate insulation pattern 130 to fill a lower portion of the first recess, and a first gate mask 150 formed on the first gate electrode 140 to fill an upper portion of the first recess. The first gate structure 160 may extend in the first direction D1 on the first region I of the substrate 100, and a plurality of first gate structures 160 may be spaced apart from each other in the second direction D2.

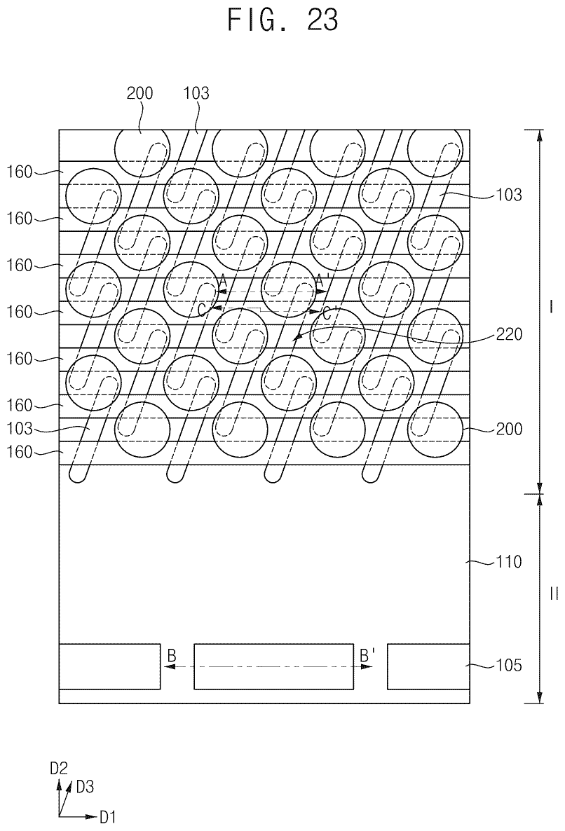

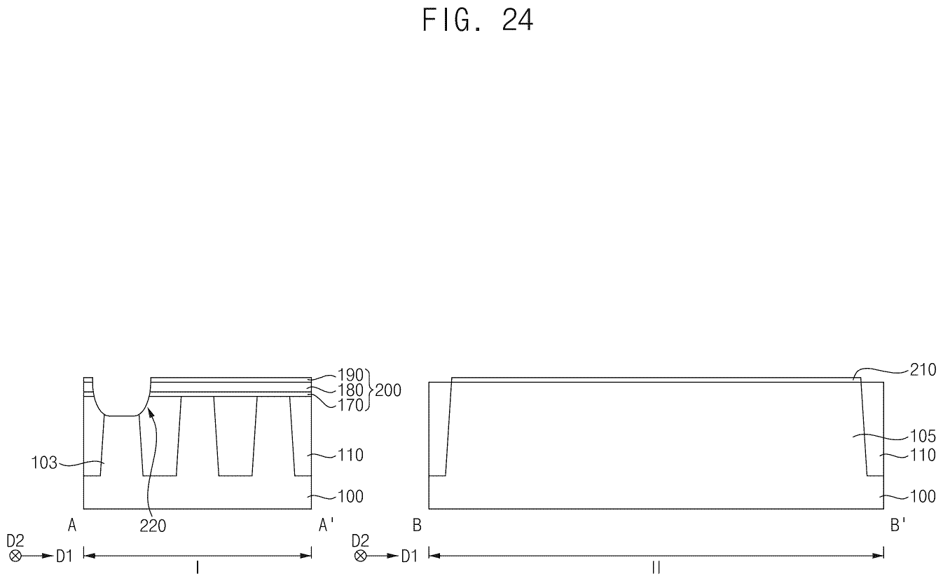

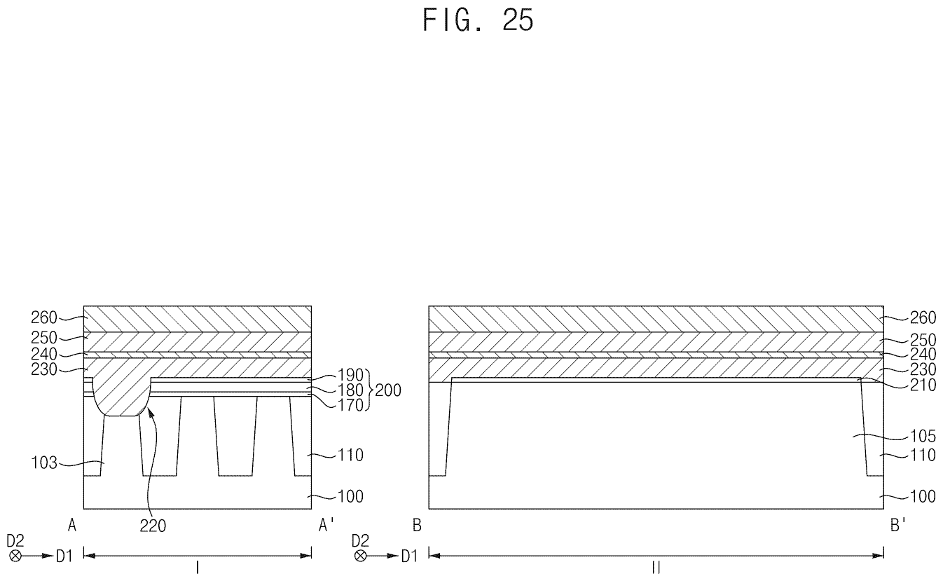

Referring to FIGS. 23 and 24, the insulation layer structure 200 may be formed on the first and second regions I and II of the substrate 100. The insulation layer structure 200 positioned on the second region II except to the second region II adjacent to the first region I may be removed. A second gate insulation layer 210 may be formed on the second active region of the second region II of the substrate 100 by performing, e.g., a thermal oxidation process.

The insulation layer structure 200 may include a first insulation layer 170, a second insulation layer 180 and a third insulation layer 190 sequentially stacked. The first and third insulation layers 170 and 190 may include an oxide such as silicon oxide, and the second insulation layer 180 may include a nitride such as silicon nitride.

Thereafter, the insulation layer structure 200 may be patterned, and then the first active pattern, the isolation pattern, and a portion of the first gate mask included in the first gate structure may be etched using the insulation layer structure 200 as an etch mask to form a first opening 220.

In various example embodiments, in plan view, the insulation layer structure 200 after the etching process may have a circular shape or elliptical shape. A plurality of insulation layer structures 200 may be spaced apart from each other, and may be aligned in each of the first and second directions D1 and D2. The insulation layer structures 200 may cover end portions in the third direction D3 of the adjacent first active patterns 103, respectively.

Referring to FIG. 25, a first conductive layer 230, a first barrier layer 240, a second conductive layer 250 and a first mask layer 260 may be sequentially stacked on the insulation layer structure 200, the first active pattern 103 and the isolation pattern 110 exposed by the first opening 220 and an upper surface a first conductive layer 230 on the first region I, and the second gate insulation layer 210 and isolation pattern 110 on the second region II. The first conductive layer 230 may fill the first opening 220.

The first conductive layer 230 may include, e.g., polysilicon doped with impurities, and the first barrier layer 240 may include a metal silicon nitride such as titanium silicon nitride (TiSiN). The second conductive layer 250 may include a metal such as tungsten, and the first mask layer 260 may include a nitride such as silicon nitride.

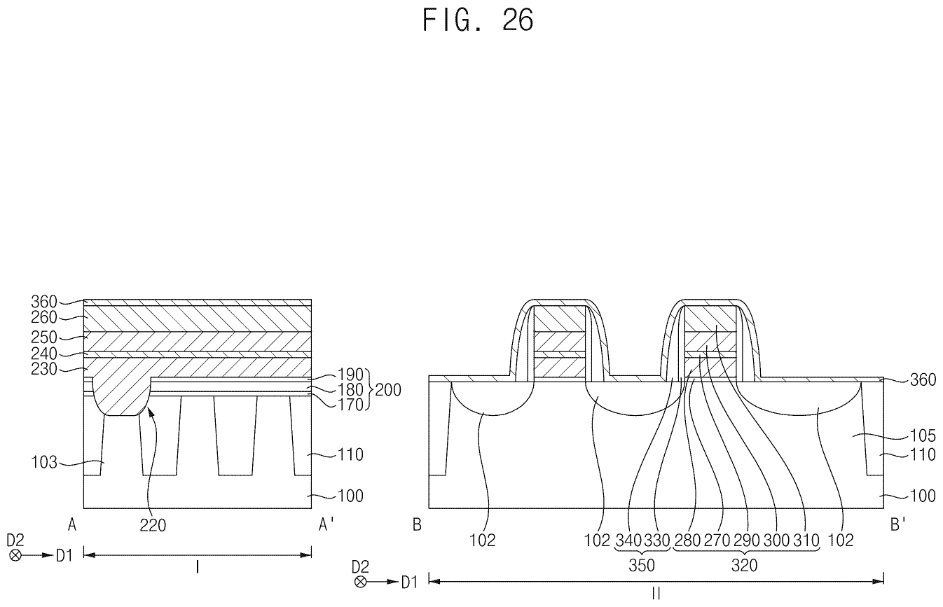

Referring to FIG. 26, a first etch mask pattern (not shown) covering the first region I and exposing a portion of the second region II may be formed on the first mask layer 260. The first mask layer 260, the second conductive layer 250, the first barrier layer 240, and the first conductive layer 230 on the second region II of the substrate 100 may sequentially etched using the first etch mask pattern as an etching mask to form a second gate structure 320 on the second region II of the substrate 100. The second gate structure 320 may include a second gate insulation pattern 270, a first conductive pattern 280, a first barrier pattern 290, and a second conductive pattern 300 and a second gate mask 310. The first conductive pattern 280, first barrier pattern 290, and second conductive pattern 300 sequentially stacked may serve as a gate electrode.

A gate spacer structure 350 may be formed on sidewalls of the second gate structure 320. The gate spacer structure 350 may include a first gate spacer 330 and a second gate spacer 340 sequentially stacked in a horizontal direction parallel to the upper surface of the substrate 100. In various example embodiments, the first gate spacer 330 may include, e.g., silicon nitride, and the second gate spacer 340 may include, e.g., silicon oxide.

After forming the second gate structure 320, first impurity regions serving as source/drain region may be formed at an upper portion of the second active pattern 105 adjacent to the second gate structure 320 by performing, e.g., an ion implantation process.

Thereafter, a first etch stop layer 360 may be formed on the first mask layer 260, the isolation pattern 110, the second active pattern 105, the second gate structure 320, and the gate spacer structure 350 on first and second regions I and II of the substrate 100. The first etch stop layer 360 may include, e.g., silicon nitride.

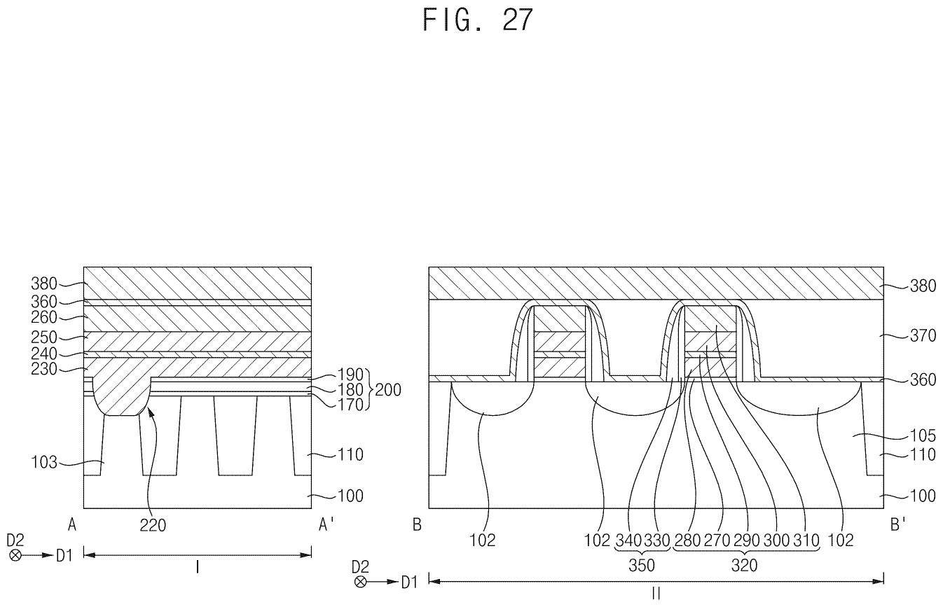

Referring to FIG. 27, a first insulating interlayer 370 may be formed on the first etch stop layer 360 to have a sufficient height covering the second gate structure 320. An upper surface of the first insulating interlayer 370 may be planarized until an upper surface of the first etch stop layer 360 positioned on the second gate structure 320 and the first mask layer 260 may be exposed. Accordingly, the first insulating interlayer 370 may fill a space between the gate spacer structures 350 on sidewalls of the second gate structures 320.

Thereafter, a first capping layer 380 including an insulation material may be formed on the first insulating interlayer 370 and the first etch stop layer 360.

The first insulating interlayer 370 may include, e.g., silicon oxide, and the first capping layer 380 may include, e.g., silicon nitride.

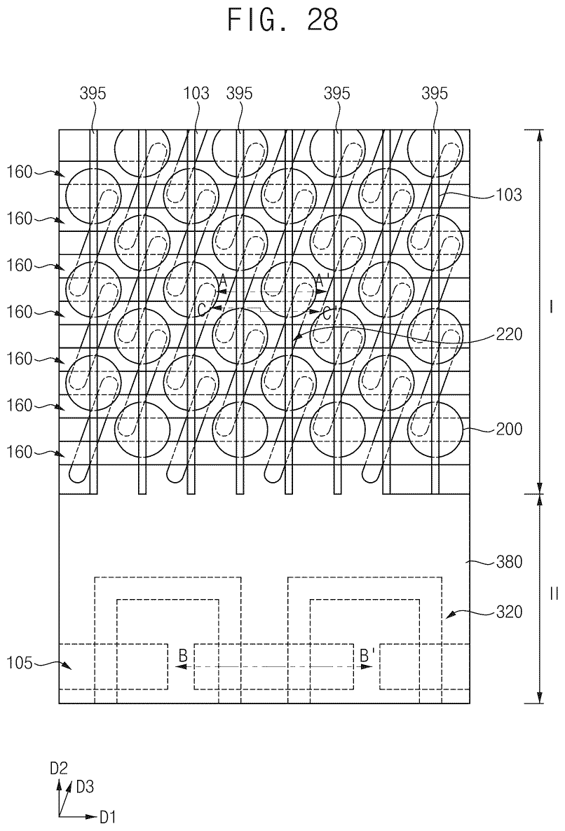

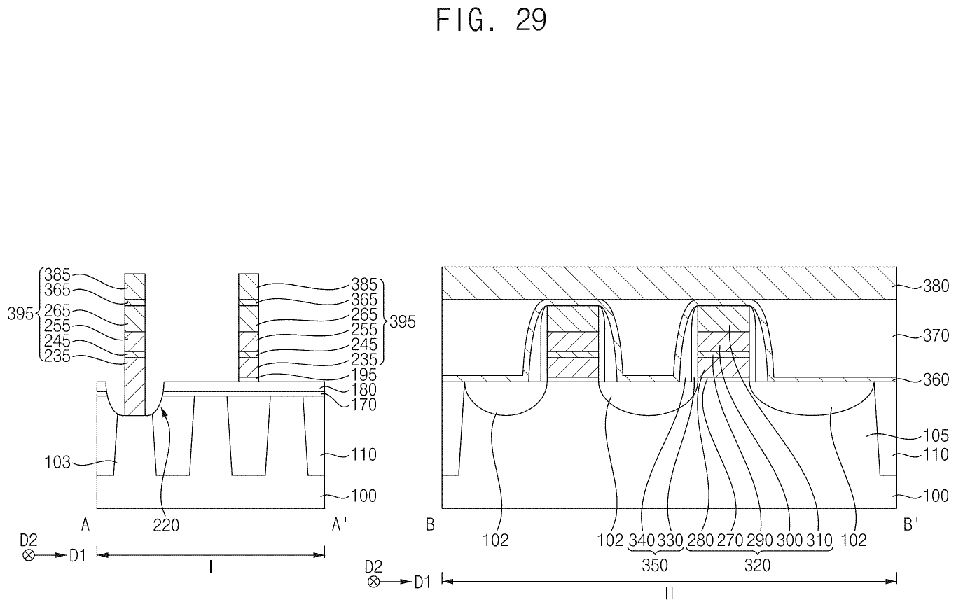

Referring to FIGS. 28 and 29, a portion of the first capping layer 380 on the first region I of the substrate 100 may be etched to form a first capping pattern 385. The first etch stop layer 360, the first mask layer 260, the second conductive layer 250, the first barrier layer 240, and the first conductive layer may be etched using the first capping pattern 385 as an etch mask.

In various example embodiments, the first capping pattern 385 may extend in the second direction D2 on the first region I of the substrate 100. A plurality of first capping patterns 385 may be spaced apart from each other in the first direction D1. The first capping layer 380 may remain on the second region II of the substrate 100.

As the etching process is performed, a third conductive pattern 235, a second barrier pattern 245, a fourth conductive pattern 255, a first mask 265, a first etch stop pattern 365, and a first capping pattern 385 may be sequentially stacked in the first opening 220 on the first region I of the substrate 100. In addition, a third insulation pattern 195, the third conductive pattern 235, the second barrier pattern 245, the fourth conductive pattern 255, the first mask 265, and the first etch stop pattern 365, and the first capping pattern 385 may be sequentially stacked on the second insulation layer 180 in the insulation layer structure 200 of outside of the first opening 220.

Hereinafter, the third conductive pattern 235, the second barrier pattern 245, the fourth conductive pattern 255, the first mask 265, the first etch stop pattern 365, and the first capping pattern 385 sequentially stacked are referred to as a bit line structure 395.

In various example embodiments, the bit line structure 395 may extend in the second direction D2 on the first region I of the substrate 100. A plurality of bit line structures 395 may be spaced apart from each other in the first direction D1. The bit line structure 395 may extend in the second direction D2 while contacting the surface of the first active pattern 103 exposed by the first opening 220.

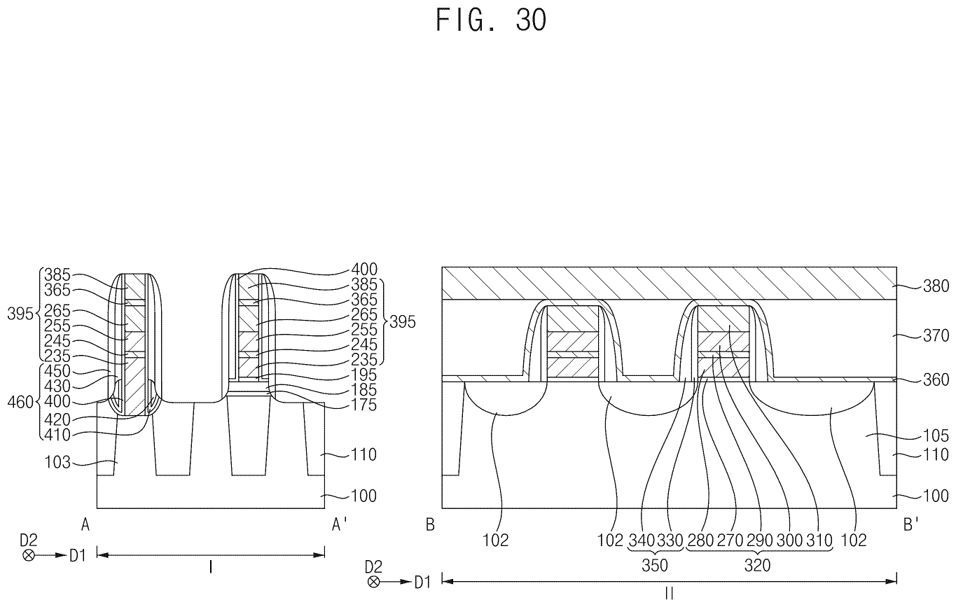

Referring to FIG. 30, a preliminary spacer structure 460 may be formed on sidewalls of the bit line structure 395. The preliminary spacer structure 460 may include a plurality of spacers. In some example embodiments, the preliminary spacer structure 460 may include a first spacer 400, a second spacer 410, a third spacer 420, a fourth spacer 430, and a fifth spacer 450 laterally stacked.

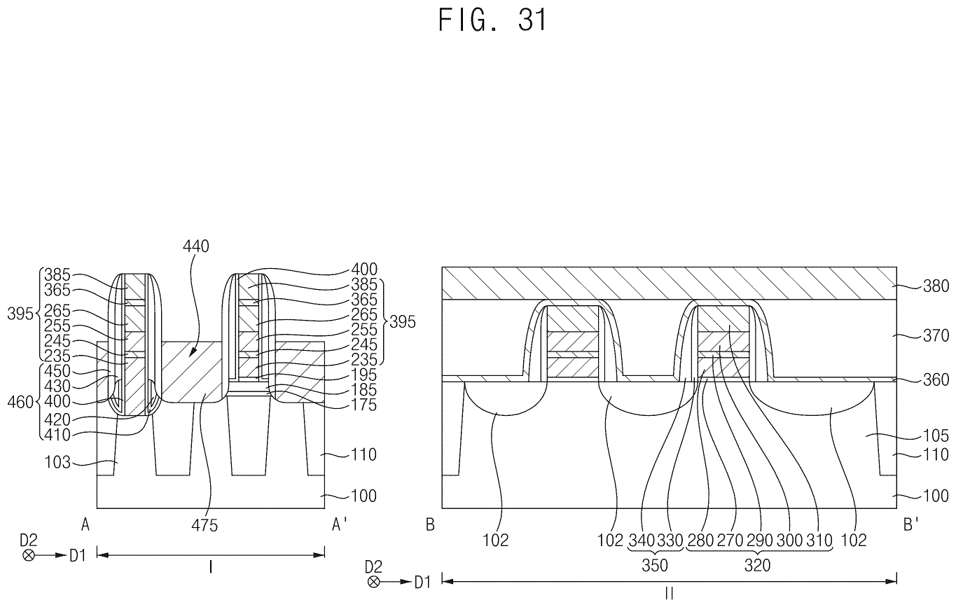

Referring to FIG. 31, a fence insulation pattern (not shown) may be formed in a gap between the preliminary spacer structures 460. For example, the fence insulation pattern may include a nitride such as silicon nitride. The fence insulation pattern may overlap the first gate structure 160.

A second opening 440 having an isolated shape may be formed between the fence insulation pattern and the bit line structure 395. A central portion in the third direction D3 of the first active pattern 103 may be exposed by the second opening 440.

A lower contact plug layer may be formed to fill the second opening 440 on the first region I of the substrate 100 to have a sufficient height. An upper portion of the lower contact plug layer may be etched to form a lower contact plug 475. In the etching process, the lower contact plug layer formed on the second region II may be completely removed. The lower contact plug 475 may include, e.g., polysilicon doped with impurities. The lower contact plug 475 may contact an isolated region of the substrate 100 between the bit line structures 395 and between the first gate structures 160.

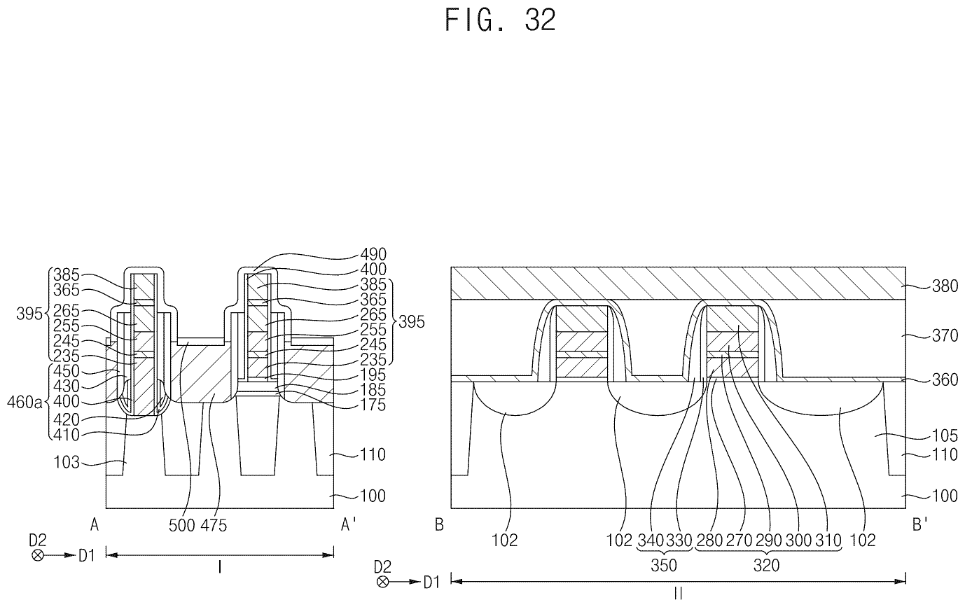

Referring to FIG. 32, in the preliminary spacer structure 460 exposed by an upper portion of the lower contact plug 475, an upper portion of the preliminary spacer structure 460 may be partially removed to form a spacer structure. For example, portions of the fourth and fifth spacers 430 and 450 may be removed.

Thereafter, a capping insulation layer may be formed on the bit line structure 395, the spacer structure 460a, the first capping pattern 385, the lower contact plug 475, and the first capping layer 380. The capping insulation layer may be anisotropically etched to form capping insulation patterns 490. Accordingly, an upper surface of the lower contact plug 475 may be exposed between the capping insulation patterns 490.

Thereafter, a first metal silicide pattern 500 may be formed on an exposed upper surface of the lower contact plug 475. The first metal silicide pattern 500 may include, e.g., cobalt silicide, nickel silicide, or titanium silicide.

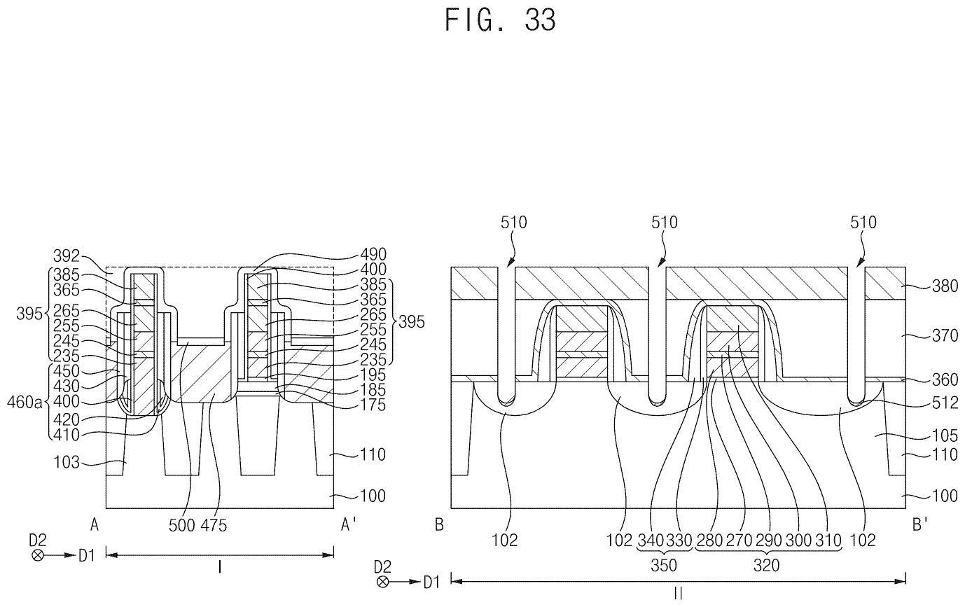

Referring to FIG. 33, a second sacrificial layer 392 may be formed on the first capping layer 380, the capping insulation pattern 490, the first metal silicide pattern 500, and the lower contact plug 475. An upper surface of the second sacrificial layer 392 may be planarized until upper surfaces of the capping insulation pattern 490 and the first capping layer 380 are exposed.

The second sacrificial layer 392 may include, e.g., a silicon on hard mask (SOH), an amorphous carbon layer (ACL), or the like.

Thereafter, a first contact hole 510 may be formed through the first capping layer 380, the first insulating interlayer 370, and the first etch stop layer 360 on the second region II of the substrate 100. The first contact hole 510 may expose the first impurity region 102 of the second active pattern 105. A second metal silicide pattern 512 may be formed on an upper surface of the second active pattern 105 exposed by a bottom of the first contact hole 510. The second sacrificial layer 392 may be removed.

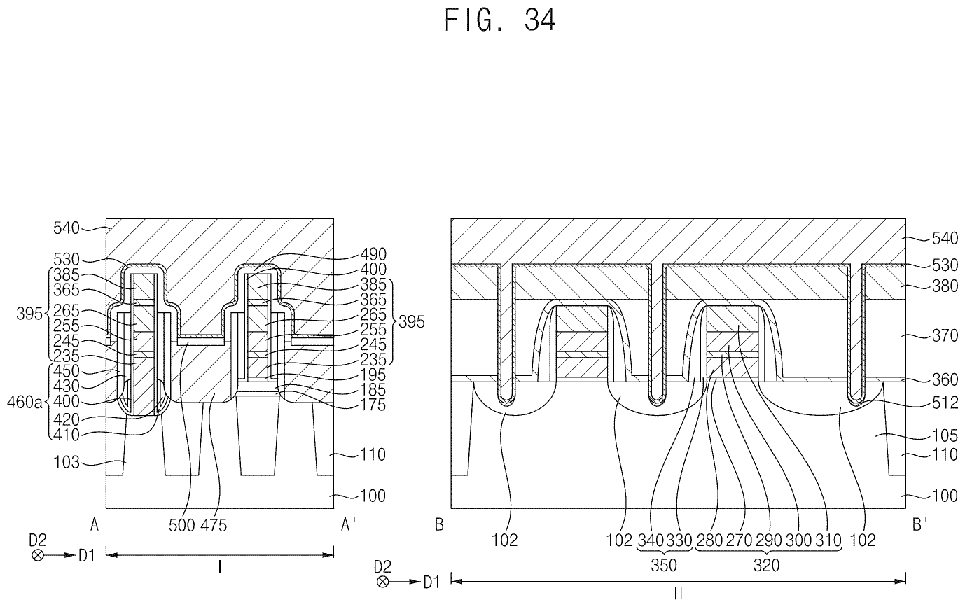

Referring to FIG. 34, a second barrier layer 530 may be formed on the capping insulation pattern 490, the first metal silicide pattern 500, and the lower contact plug 475 on the first region I of the substrate 100, and on the first capping layer 380, a surface of the first contact holes 510, and the second metal silicide pattern 512 on the second region II of the substrate 100. A first metal layer 540 may be formed on the second barrier layer 530 to fill the first contact hole 510 and a space between the bit line structures 395.

In some example embodiments, the second barrier layer 530 may include titanium, titanium nitride, tantalum, or tantalum nitride, and the first metal layer 540 may include tungsten.

Thereafter, a planarization process may be additionally performed on the upper part of the first metal layer 540. The planarization process may include, e.g., a chemical mechanical polishing (CMP) process and/or an etch back process.

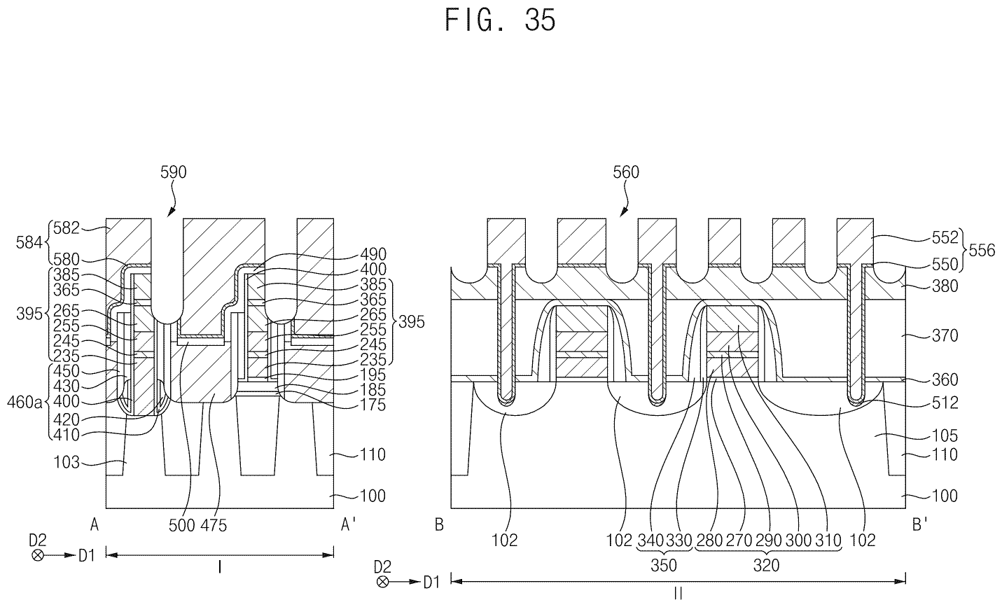

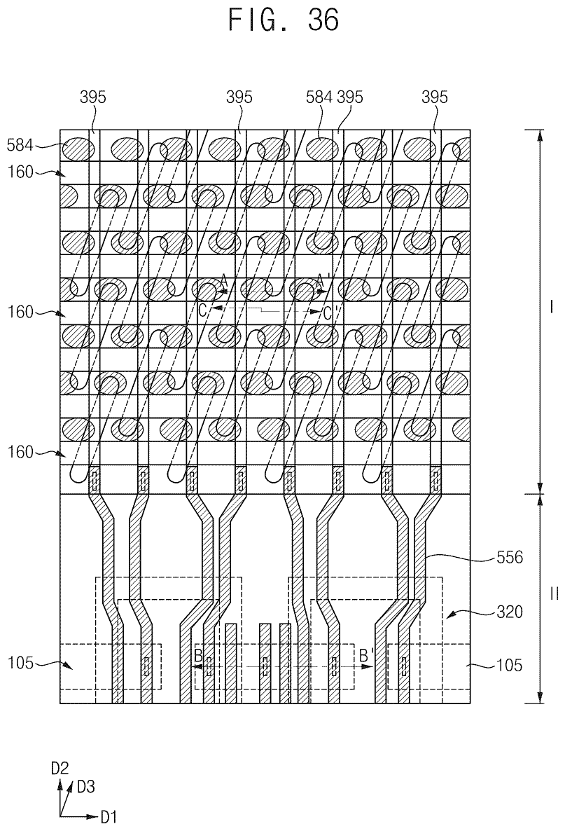

Referring to FIGS. 35 and 36, a third etch mask pattern (not shown) may be formed on the first metal layer 540. The first metal layer 540, the second barrier layer 530, and the first capping layer 380 on the first and second regions I and II of the substrate 100 may be etched using the third etch mask pattern as an etching mask. Thus, a landing pad pattern 584 and a third opening 590 may be formed on the first region I of the substrate 100, and first conductive structures 556 and fourth openings 560 may be formed on the second region II of the substrate 100.

The landing pad pattern 584 may include a third barrier pattern 580 and a first metal pattern 582. The first conductive structure 556 may include a fourth barrier pattern 550 and a second metal pattern 552.

The first conductive structure 556 may include a first contact plug in the first contact hole 510 and a first conductive line on the first capping layer 380 and the first contact plug. For example, the first contact plug may contact the first impurity region 102 of the second region II of the substrate 100. The first conductive structures 556 may be electrically connected to a transistor for a peripheral circuit formed on the second region II of the substrate 100.

The third etch mask pattern may be removed.

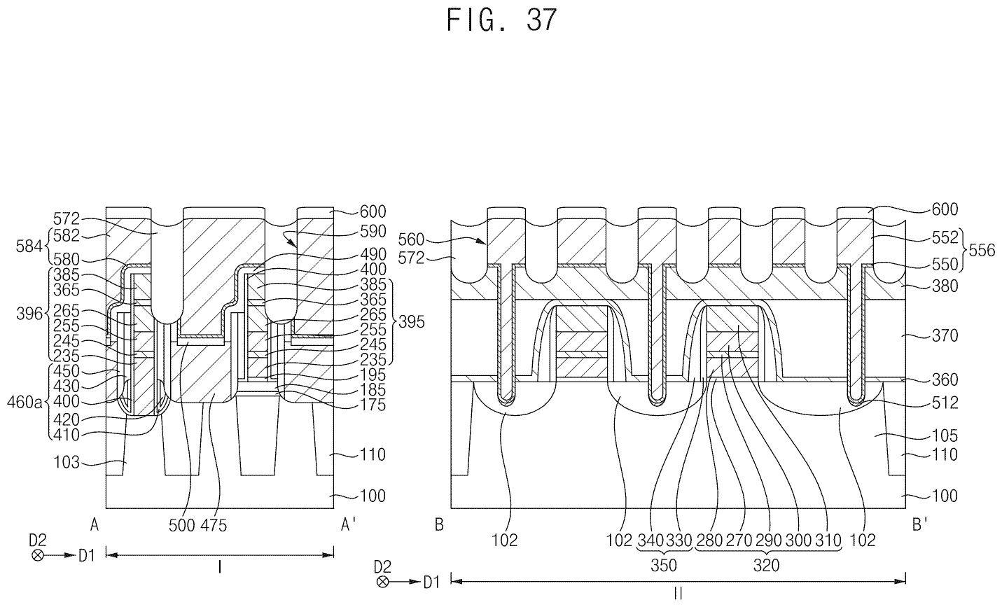

Referring to FIG. 37, a fourth insulation layer may be formed on the landing pad pattern 584 and the first conductive structure 556 to fill the third opening 590 and the fourth opening 560. The fourth insulation layer may include, e.g., silicon nitride.

Thereafter, the fourth insulation layer may be planarized until upper surfaces of the first conductive structure 556 and the landing pad pattern 584 are exposed to form first upper insulation patterns 572 in the third and fourth openings 590 and 560.

In various example embodiments, an upper surface of the first upper insulation pattern 572 may be lower than the upper surfaces of the first conductive structure 556 and the landing pad pattern 584.

The lower contact plug 475, the first metal silicide pattern 500, and the landing pad pattern 584 sequentially stacked on the first region I of the substrate 100 may serve as a contact plug structure.

The first metal pattern 582 and the second metal pattern 552 comprising the landing pad pattern 584, and the first conductive structure 566 may include, e.g., tungsten. Hereinafter, it may be explained that the first and second metal patterns 582 and 552 include tungsten.

The upper surfaces of the first and second metal patterns 582 and 552 may be exposed, and thus the upper surfaces of the first and second metal patterns 582 and 552 may react with oxygen by a native oxidation to form a preliminary tungsten oxide layer 600.

In various example embodiments, an ashing process, which is a heat treatment process introducing oxygen, may be further performed on the first and second metal patterns 582 and 552. When the ashing process is performed, a preliminary tungsten oxide layer 600 may be formed on the upper surfaces of the first and second metal patterns 582 and 552 to have a relatively thick thickness rather than the preliminary tungsten oxide layer formed by the native oxidation.

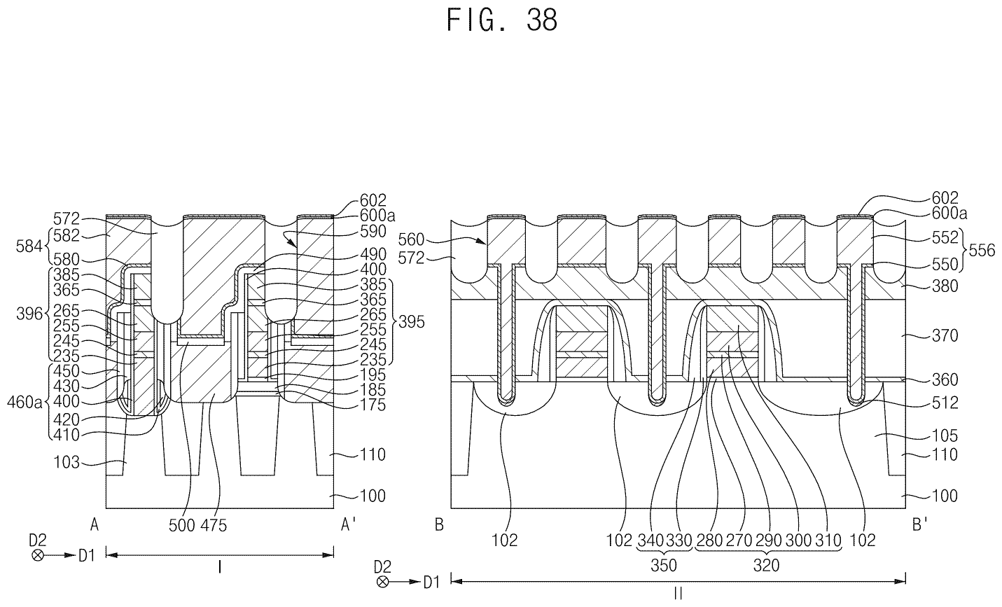

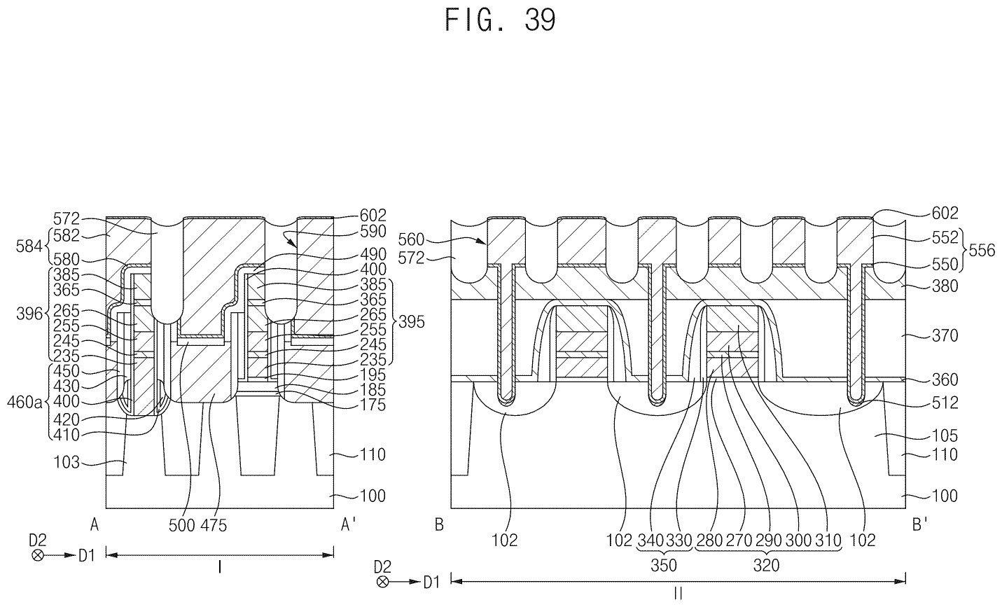

Referring to FIGS. 38 and 39, a surface plasma treatment process may be performed on the preliminary tungsten oxide layer 600. Accordingly, at least a portion of the preliminary tungsten oxide layer 600 may be removed to form a tungsten oxide layer 600a, and a protective layer 602 may be generated on the tungsten oxide layer 600a.

In various example embodiments, the surface plasma treatment process may include a CO plasma treatment process. In this case, a portion of the preliminary tungsten oxide layer 600 may be removed to form the tungsten oxide layer 600a having a thickness less than a thickness of the preliminary tungsten oxide layer 600. Further, the protective layer 602 may be formed on the tungsten oxide layer 600a by generating a W—O—C bond or a W—C bond on the tungsten oxide layer 600a. The protective layer 602 may be, e.g., a WOC layer or a WN layer.

For example, the surface plasma treatment process may be performed only the CO plasma treatment process. For example, the surface plasma treatment process may include the CO plasma treatment process and a hydrogen plasma treatment process. The CO plasma treatment process may be performed after performing the hydrogen plasma treatment process. When the hydrogen plasma treatment process is performed, the entire, or portions of, the preliminary tungsten oxide layer 600 may be removed.

In some example embodiments, the surface plasma treatment process may include an NH₃ plasma treatment process. In this case, a portion of the preliminary tungsten oxide layer 600 may be removed to form the tungsten oxide layer 600a. Therefore, the tungsten oxide layer 600a may be formed to have a thickness less than a thickness of the preliminary tungsten oxide layer 600. Further, the protective layer 602 may be formed on the tungsten oxide layer 600a by generating a W—O—N bond or a W—N bond on the tungsten oxide layer 600a. The protective layer 602 may include nitrogen, and may be, e.g., a WON layer or a WN layer.

For example, the surface plasma treatment process may be performed only the NH₃ plasma treatment process. For example, the surface plasma treatment process may include the NH₃ plasma treatment process and the hydrogen plasma treatment process. The surface plasma treatment process may be performed after performing the hydrogen plasma treatment process.

In some example embodiments, the surface plasma treatment process may include only hydrogen plasma treatment.

In some example embodiments, the surface plasma treatment process may include the CO plasma treatment and the NH₃ plasma treatment processes.

When the CO plasma treatment process or the NH₃ plasma treatment process is performed, the tungsten oxide layer 600a and the protective layer 602 may be formed on the first and second metal patterns 582 and 552, as shown in FIG. 38.

When the CO plasma treatment process or NH₃ plasma treatment process is performed after completely removing the preliminary tungsten oxide layer 600 by the hydrogen plasma treatment process, only the protective layer 602 may be formed on the first and second metal patterns 582 and 552, as shown in FIG. 39.

In the following drawings, the tungsten oxide layer 600a and the protective layer 602 may be illustrated on the first and second metal patterns 582 and 552.

Alternatively, only the hydrogen plasma treatment may be performed, so that the protective layer may not be formed on the first and second metal patterns 582 and 552. Therefore, only the tungsten oxide layer may be formed on the first and second metal patterns 582 and 552, or the tungsten oxide layer may not be formed on the first and second metal patterns 582 and 552.

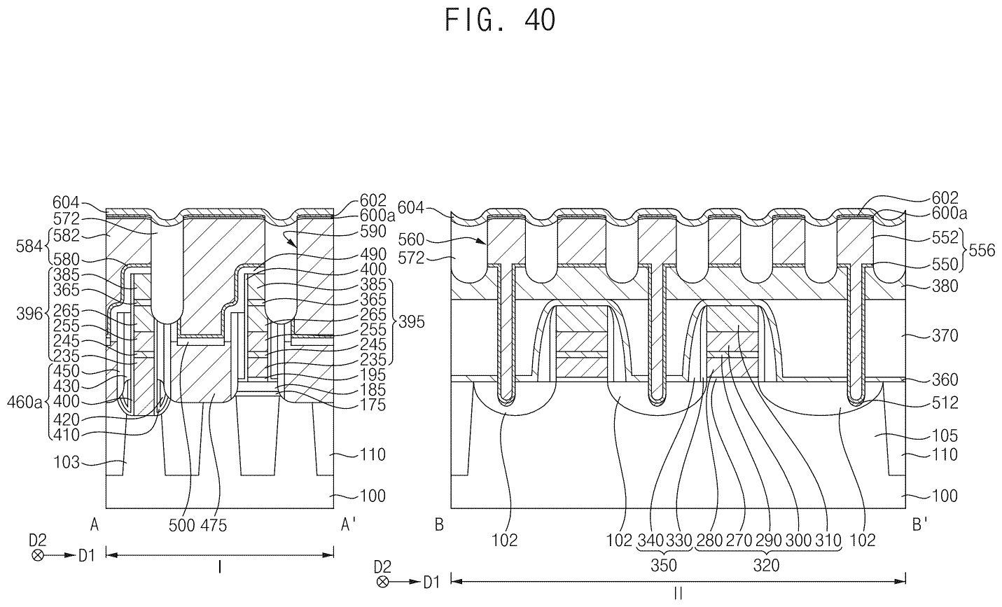

Referring to FIG. 40, a second etch stop layer 604 may be formed on the protective layer 602 and the first upper insulation pattern 572. The second etch stop layer 604 may include, e.g., SiBN, SiCN, or SiN. For example, the second etch stop layer 604 may include SiBN as a material through which the hydrogen can diffuse.

The upper surface of the protective layer 602 may become more uniform by performing the surface plasma treatment process, the second etch stop layer 604 may be formed on the protective layer 602 to have a more uniform thickness.

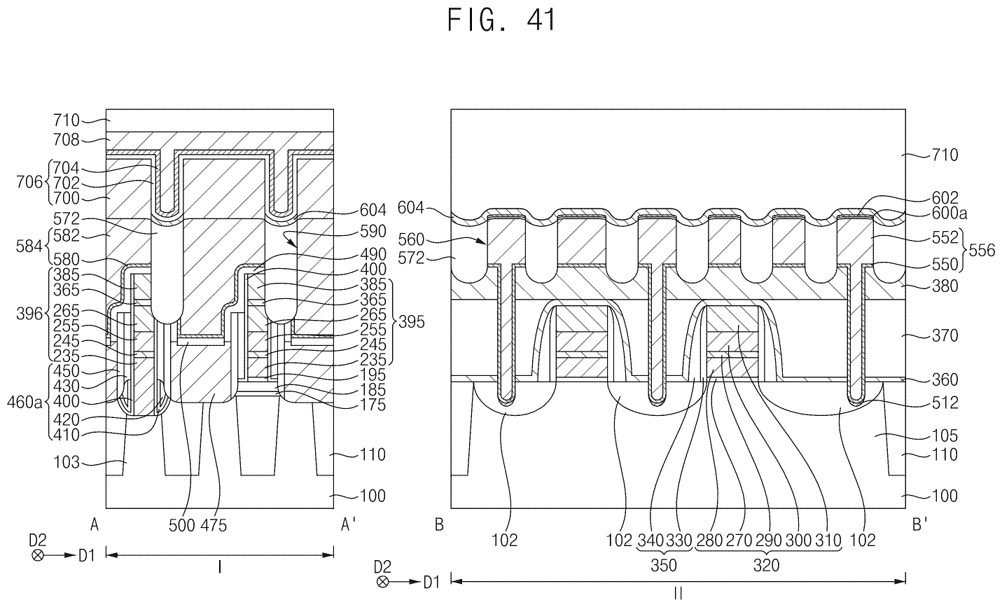

Referring to FIG. 41, a cell capacitor 706 may be formed through the second etch stop layer 604, the protective layer 602, and the tungsten oxide layer 600a, and may contact the landing pad pattern 584 on the first region I of the substrate 100. The cell capacitor 706 may include a lower electrode 700, a dielectric layer 702, and an upper electrode 704. A plate electrode 708 may be formed on the upper electrode 704. The plate electrode 708 may include, e.g., polysilicon and/or silicon germanium. In some example embodiments, the cell capacitor 706 may not be formed on the second region II of the substrate 100.

In the process for forming the cell capacitor 706, most of the protective layer 602 and the tungsten oxide layer 600a on the first region I of the substrate 100 may be removed.

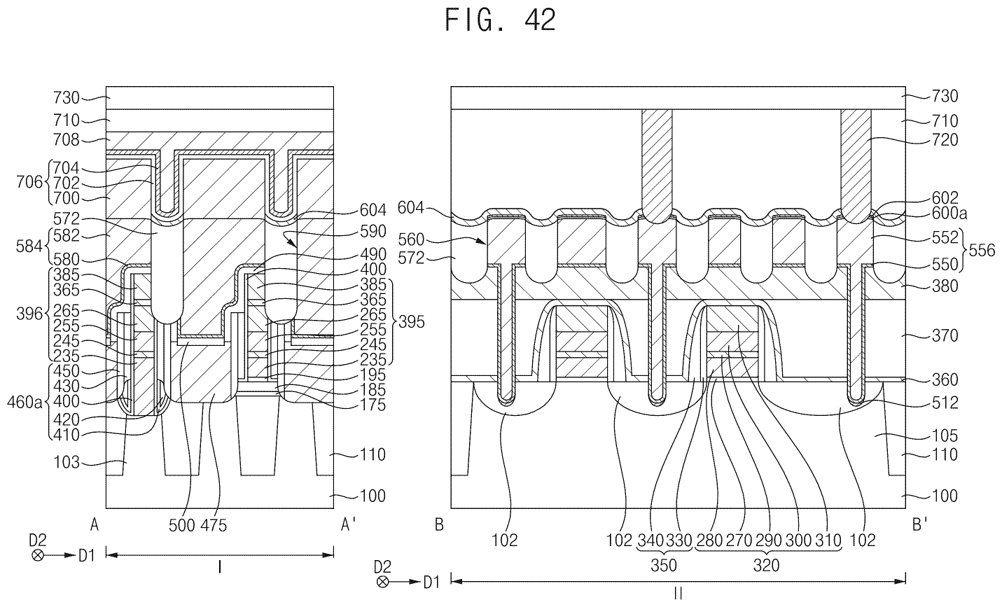

Referring to FIG. 42, a second insulating interlayer 710 may be formed to cover the plate electrode 708 and the second etch stop layer 604.

A planarization process may be performed on the second insulating interlayer 710. Accordingly, an upper surface of the second insulating interlayer 710 may be substantially flat. The cell capacitor 706 may be formed only on the first region I of the substrate 100, and thus a thickness of the second insulating interlayer 710 on the second region II of the substrate 100 may be greater than the thickness of the second insulating interlayer 710 on the first region I of the substrate 100.

An upper contact plug 720 may be formed through the second insulating interlayer inter 710, the second etch stop layer 604, the protective layer 602, and the tungsten oxide layer 600a on the second region II of the substrate 100, and may contact the second metal pattern 552. The upper contact plug 720 may include metal. The upper contact plug 720 may include a barrier metal pattern and a metal pattern. The metal pattern may include, e.g., tungsten.

Thereafter, multilayer interconnections (not shown) may be formed on the upper contact plug 720, and a hydrogen diffusion insulation layer 730 for hydrogen diffusion may be formed on the multilayer interconnections. For example, the hydrogen diffusion insulation layer 730 may be a high density plasma (HDP) oxide layer. The hydrogen included in the hydrogen diffusion insulation layer 730 may be diffused to the surface of the substrate 100. Dangling bonds on the surface of the substrate 100 may be removed by the hydrogen, and thus characteristics of the semiconductor device may be improved.

The semiconductor device may be manufactured by the above-described processes.

The semiconductor device may have the following structural characteristics.

Referring to FIGS. 36 and 42 again, the semiconductor device may be formed on the substrate 100 including the first region I and the second region II.

First active patterns 103 may be formed on the first region I of the substrate 100, and second active patterns 105 may be formed on the second region II of the substrate 100. An isolation pattern 110 may be formed between the first and second active patterns 103 and 105.

A first gate structure 160, a bit line structure 395, a spacer structure 460a, a first upper insulation pattern 572, a contact plug structure, and a cell capacitor 706 may be formed on the first region I of the substrate 100. A second gate structure 320, a first insulating interlayer 370, a first capping layer, a first conductive structure 556, a tungsten oxide layer 600a, a protective layer 602, a first upper insulation pattern 572, a second etch stop layer 604, a second insulating interlayer 710, and an upper contact plug 720 may be formed on the second region II of the substrate 100. In some example embodiments, the tungsten oxide layer 600a may not be formed on the first conductive structure 556, and a protective layer 602 may be formed on the first conductive structure 556.

In addition, an upper wiring and a hydrogen diffusion insulation layer 730 may be further included on the first and second regions I and II of the substrate 100.

As shown in FIG. 22, the first gate structure 160 may be buried in the first region I of the substrate 100. The first gate structures 160 may extend in the first direction D1. A plurality of first gate structures 160 may be spaced apart from each other in the second direction D2. Impurity regions may be formed at upper portions of the first active pattern 103 adjacent to the first gate structure 160. The first gate structure 160 and the impurity regions may serve as a cell transistor.

An insulation pattern structure may be disposed on the first active pattern 103, the isolation pattern 110, and the capping mask pattern 114 on the first region I. The insulation pattern structure may include a first insulation pattern 175, a second insulation pattern 185, and a third insulation pattern 195 sequentially stacked.

A bit line structure 395 may be disposed on the first region I, and the bit line structure 395 may include a third conductive pattern 235, a second barrier pattern 245, a fourth conductive pattern 255, a first mask 265, a first etch stop pattern 365 and a first capping pattern 385 sequentially stacked. In various example embodiments, the bit line structure 395 may be formed on the first active pattern 103 and the third insulation pattern 195, and may extend in the second direction D2. The plurality of bit line structures 395 may be spaced apart from each other in the first direction D1. A bottom of the bit line structure 395 may include a portion contacting a partial surface of the first active pattern 103 and a portion contacting the third insulation pattern 195.

A second gate structure 320 may be disposed on the second active pattern 105 on the second region II of the substrate 100.

The second gate structure 320 may include a second gate insulation pattern 270, a first conductive pattern 280, a first barrier pattern 290, a second conductive pattern 300, and a second gate mask 310 sequentially stacked.

A gate spacer structure 350 may be formed on sidewalls of the second gate structure 320. The gate spacer structure 350 may include, e.g., a first gate spacer 330 and a second gate spacer 340.

First impurity regions 102 may be disposed at the second active pattern 105 adjacent to the second gate structure 320. The second gate structure 320 and the first impurity regions 102 may serve as a transistor for peripheral circuits.

A first etch stop layer 360 may be formed along surface profiles of the second gate structure 320, the gate spacer structure 350, and the second active pattern 105. The first etch stop layer 360 may include, e.g., silicon nitride.

A first insulating interlayer 370 may be disposed on the first etch stop layer 360 to fill a space between the second gate structures 320. A first capping layer 380 may be disposed on the first insulating interlayer 370 and the first etch stop layer 360. The first insulating interlayer 370 may include, e.g., silicon oxide, and the first capping layer 380 may include, e.g., silicon nitride.

A stacked structure including the third conductive pattern 235, the second barrier pattern 245, the fourth conductive pattern 255, and the first mask 265 included in the bit line structure 395 may be substantially the same a stacked structure including the first conductive pattern 280, the first barrier pattern 290, the second conductive pattern 300, and the second gate mask 310 included in the second gate structure 320.

The first etch stop pattern 365 of the bit line structure 395 may be formed by a deposition process the same as a deposition process of the first etch stop layer 360 on the second region II of the substrate 100. Therefore, the first etch stop pattern 365 and the first etch stop layer 360 may include the same material. The first capping pattern 385 of the bit line structure 395 may be formed by a deposition process the same as the first capping layer 380 on the second region II of the substrate 100. Therefore, the first capping pattern 385 and the first capping layer 380 may include the same material.

A spacer structure may be disposed on sidewalls of the bit line structure 395. The spacer structure may include a plurality of spacers stacked from sidewalls of the bit line structure 395. In some example embodiments, the bit line structure 395 may include a first spacer 400, a second spacer 410, a third spacer 420, a fourth spacer 430 and a fifth spacer 450 sequentially stacked from the sidewalls of the bit line structure 395.

A fence insulation pattern (not shown) may be disposed on the first gate structure 160 positioned between the bit line structures 395.

A second opening 440 exposing the first active pattern 103 may be formed between the bit line structures 395 and the fence insulation patterns. A lower contact plug 475 and a landing pad pattern 584 may be disposed in the second opening 440. The lower contact plug 475 and the landing pad pattern 584 may serve as a contact plug structure.

The lower contact plug 475 may include, e.g., polysilicon doped with impurities.

In various example embodiments, a first metal silicide pattern 500 may be disposed between the lower contact plug 475 and the landing pad pattern 584. The first metal silicide pattern 500 may include, e.g., cobalt silicide, nickel silicide, or titanium silicide.

A first upper insulation pattern 572 may be disposed between the landing pad patterns 584.

A first contact hole 510 may pass through the first capping layer 380, the first insulating interlayer 370, and the first etch stop layer 360, on the second region II of the substrate 100. The first impurity region 102 may be exposed by the first contact hole 510.

A first conductive structure 556 may be disposed on the first capping layer 380 to fill he first contact hole 510. The first conductive structure 556 may include a fourth barrier pattern 550 and a second metal pattern 552. The first conductive structure 556 may include a first contact plug in the first contact hole 510 and a first conductive line on the first contact plug and the first capping layer 380. The second metal pattern 552 may include, e.g., tungsten.

A second metal silicide pattern 512 may be disposed between a bottom of the first contact plug and the second active pattern 105.

A fourth opening 560 may be formed between the first conductive structures 556.

A first upper insulation pattern 572 may be formed in the fourth opening 560. An upper surface of the first upper insulation pattern 572 may be lower than an upper surface of the second metal pattern 552.

In some example embodiments, the tungsten oxide layer 600a and the protective layer 602 may be stacked on the upper surface of the second metal pattern 552. The tungsten oxide layer 600a and the protective layer 602 may not be formed on the first upper insulation pattern 572. The protective layer 602 may include, e.g., WOC, WC, WON, WN, etc.

In some example embodiments, only the protective layer 602 may be disposed on the second metal pattern 552.

The second etch stop layer 604 may cover the protective layer 602 and the first upper insulation pattern 572. The second etch stop layer 604 may include, e.g., SiBN, SiCN, or SiN. For example, the second etch stop layer 604 may include SiBN as a material through which the hydrogen can diffuse.

The cell capacitor 706 may pass through the second etch stop layer 604, and may contact the landing pad pattern 584 on the first region I of the substrate 100. A plate electrode 708 may be further included on the upper electrode 704.

The second insulating interlayer 710 may cover the cell capacitor 706 and the second etch stop layer 604. An upper contact plug 720 may pass through the second insulating interlayer 710, the second etch stop layer 604, the protective layer 602, and the tungsten oxide layer 600a. The upper contact plug 720 may contact the second metal pattern 552.

Multilayer wiring and the hydrogen diffusion insulation layer 730 for hydrogen diffusion may be disposed on the upper contact plug 720.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of the present inventive concept.

What is claimed is:

1. A method for manufacturing a semiconductor device, comprising:
forming an insulating interlayer on a substrate;
forming tungsten patterns inside and on the insulating interlayer;
forming an insulation pattern on the insulating interlayer to fill a space between the tungsten patterns, and the insulation pattern having a lowest point of an upper surface lower than an upper surface of each of the tungsten patterns;
forming a preliminary tungsten oxide layer on the upper surface of each of the tungsten patterns;
performing a first surface plasma treatment on the preliminary tungsten oxide layer to remove at least a portion of the preliminary tungsten oxide layer to form a tungsten oxide layer and a protective layer on the tungsten oxide layer; and
forming an etch stop layer on the protective layer and the insulation pattern.

2. The method of claim 1, wherein the first surface plasma treatment includes a CO plasma treatment.

3. The method of claim 2, wherein the protective layer includes a WOC layer or a WC layer.

4. The method of claim 1, wherein the first surface plasma treatment includes a NH₃ plasma treatment.

5. The method of claim 4, wherein the protective layer includes a WON layer or a WN layer.

6. The method of claim 1, wherein a hydrogen plasma treatment is further performed to remove an entire, or a portion of, the preliminary tungsten oxide layer, before performing the first surface plasma treatment.

7. The method of claim 1, wherein the etch stop layer includes SiBN, SiCN, or SiN.

8. The method of claim 1, wherein the first surface plasma treatment is performed so that a sum of thicknesses of the tungsten oxide layer and the protective layer is less than a thickness of the preliminary tungsten oxide layer.

9. The method of claim 1, wherein after forming the etch stop layer, the method further comprises:
forming a second insulating interlayer on the etch stop layer; and
forming contact plugs passing through the second insulating interlayer, the etch stop layer, the protective layer, and the tungsten oxide layer, and contacting each of the tungsten patterns.

10. The method of claim 1, wherein forming the tungsten patterns comprises:
etching the insulating interlayer to form contact holes exposing an upper surface of the substrate;
forming a tungsten layer on the insulating interlayer to fill the contact holes; and
patterning the tungsten layer on the insulating interlayer.

11. The method of claim 1, wherein forming the preliminary tungsten oxide layer includes performing a heat treatment process introducing oxygen.

12. A method for manufacturing a semiconductor device, comprising:
forming bit line structures on a cell region of a substrate;
forming gate structures on a peripheral circuit region of the substrate;
forming an insulating interlayer covering the gate structures on the peripheral circuit region of the substrate;
forming lower contact plugs contacting the substrate and landing pad patterns including tungsten on the lower contact plugs, the lower contact plugs and the landing pad patterns between the bit line structures;
forming first conductive structures including tungsten on the insulating interlayer, the first conductive structures passing through the insulating interlayer and contacting a surface of the substrate;
forming insulation patterns between the landing pad patterns and between the first conductive structures;
forming a preliminary tungsten oxide layer on upper surfaces of the landing pad patterns and the first conductive structures, respectively;
performing a first surface plasma treatment on the preliminary tungsten oxide layer to remove at least a portion of the preliminary tungsten oxide layer to form a tungsten oxide layer and a protective layer on the tungsten oxide layer;
forming an etch stop layer on the protective layer and the insulation pattern;
forming capacitors on the landing pad patterns, the capacitors passing through the etch stop layer, the protective layer, and the tungsten oxide layer on the cell region of the substrate; and
forming contact plugs contacting an upper surface of the first conductive structures, the contact plugs passing through the etch stop layer, the protective layer, and the tungsten oxide layer on the peripheral circuit region of the substrate.

13. The method of claim 12, wherein the first surface plasma treatment includes a CO plasma treatment or a NH₃ plasma treatment.

14. The method of claim 13, wherein the protective layer includes a WOC layer, a WC layer, a WON layer, or a WN layer.

15. The method of claim 12, wherein a hydrogen plasma treatment is further performed to remove an entire, or a portion of, the preliminary tungsten oxide layer, before performing the first surface plasma treatment.

16. The method of claim 12, wherein the etch stop layer includes SiBN, SiCN, or SiN.

17. The method of claim 12, wherein the first surface plasma treatment is performed so that a sum of thicknesses of the tungsten oxide layer and the protective layer is less than a thicknesses of the preliminary tungsten oxide layer.

18. A method for manufacturing a semiconductor device, comprising:
forming lower structures on a substrate;
forming a first lower insulating interlayer including silicon oxide on the lower structures;
forming a second lower insulating interlayer including silicon nitride on the first lower insulating interlayer;
forming tungsten patterns on the second lower insulating interlayer, and the tungsten patterns passing through the first and second lower insulating interlayers;
forming insulation patterns including silicon nitride on the second lower insulating interlayers, the insulation patterns filling a space between the tungsten patterns and having a lowest point of an upper surface lower than an upper surface of each of the tungsten patterns;
forming a preliminary tungsten oxide layer on the upper surface of each of the tungsten patterns;
performing a CO plasma treatment on the preliminary tungsten oxide layer to remove at least a portion of the preliminary tungsten oxide layer to form a tungsten oxide layer and a protective layer on the tungsten oxide layer, the protective layer including at least tungsten and carbon; and
forming an etch stop layer on the protective layer and the insulation patterns.

19. The method of claim 18, wherein a hydrogen plasma treatment is further performed to remove an entire, or a portion of, the preliminary tungsten oxide layer, before performing the CO plasma treatment.

20. The method of claim 18, wherein the etch stop layer includes SiBN, SiCN, or SiN.
